(19) United States
(12) Patent Application Publication
(10) Pub. No.: US 2026/0129832 A1
(43) Pub. Date: May 7, 2026

(54) SEMICONDUCTOR DEVICE WITH VERTICAL CHANNEL LAYER AND METHOD FOR FABRICATING THE SAME

(71) Applicant: NANYA TECHNOLOGY CORPORATION, NEW TAIPEI CITY (TW)

(72) Inventor: TSENG-FU LU, NEW TAIPEI CITY (TW)

(21) Appl. No.: 18/976,464

(22) Filed: Dec. 11, 2024

Related U.S. Application Data
(63) Continuation of application No. 18/938,457, filed on Nov. 6, 2024.

(51) Int. Cl. H10B 12/00

(52) U.S. Cl. CPC H10B 12/315; H10B 12/03; H10B 12/05; H10B 12/482; H10B 12/485

(57) ABSTRACT

The present application discloses a semiconductor device and a method for fabricating the semiconductor device. The semiconductor device includes a substrate; a channel layer positioned over the substrate, extending along a first direction perpendicular to a top surface of the substrate, and including an inverted trapezoid cross-sectional profile; and a word line including a word-line dielectric layer conformally and laterally surrounding the channel layer, and a word-line conductive layer laterally and partially surrounding the word-line dielectric layer, extending along a second direction parallel to the top surface of the substrate, and including an inverted trapezoid cross-sectional profile.

### CROSS-REFERENCE TO RELATED APPLICATION

This application is a continuation application of U.S. Non-Provisional application Ser. No. 18/938,457 filed Nov. 6, 2024, which is incorporated herein by reference in its entirety.

### TECHNICAL FIELD

The present disclosure relates to a semiconductor device and a method for fabricating the semiconductor device, and more particularly, to a semiconductor device with a vertical channel layer and a method for fabricating the semiconductor device with the vertical channel layer.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate; a channel layer positioned over the substrate, extending along a first direction perpendicular to a top surface of the substrate, and including an inverted trapezoid cross-sectional profile; and a word line including a word-line dielectric layer conformally and laterally surrounding the channel layer, and a word-line conductive layer laterally and partially surrounding the word-line dielectric layer, extending along a second direction parallel to the top surface of the substrate, and including an inverted trapezoid cross-sectional profile.

Another aspect of the present disclosure provides a semiconductor device including a substrate; a channel layer positioned over the substrate and extending along a first direction perpendicular to a top surface of the substrate, wherein a width of a top surface of the channel layer is greater than a width of a bottom surface of the channel layer; and a word line including a word-line dielectric layer conformally and laterally surrounding the channel layer, and a word-line conductive layer laterally and partially surrounding the word-line dielectric layer and extending along a second direction parallel to the top surface of the substrate, wherein a width of a top surface of the word-line conductive layer is greater than a width of a bottom surface of the word-line conductive layer.

Another aspect of the present disclosure provides a method for fabricating a semiconductor device including providing a substrate; forming a lower dielectric layer over the substrate; forming a middle dielectric layer on the lower dielectric layer; forming a word-line trench penetrating the middle dielectric layer, exposing the lower dielectric layer, and including an inverted trapezoid cross-sectional profile; forming a word-line conductive layer filling the word-line trench; forming an upper dielectric layer on the middle dielectric layer; forming a channel opening penetrating the upper dielectric layer, the word-line conductive layer, and the lower dielectric layer to expose the substrate; and conformally forming a word-line dielectric layer on a sidewall of the channel opening; and forming a channel layer filling the channel opening. The word-line conductive layer and the word-line dielectric layer together configure a word line.

Due to the design of the semiconductor device of the present disclosure, the process window for forming the channel layer may be increased by employing the word-line conductive layer and the channel layer with the inverted trapezoid cross-sectional profile. As a result, the defect for fabricating the semiconductor device may be decreased and the yield for fabricating the semiconductor device may be improved.

The foregoing has outlined rather broadly the features and technical advantages of the present disclosure in order that the detailed description of the disclosure that follows may be better understood. Additional features and advantages of the disclosure will be described hereinafter and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device in accordance with one embodiment of the present disclosure;

FIG. 2 illustrates, in a schematic top-view diagram, an intermediate semiconductor device in accordance with one embodiment of the present disclosure;

FIG. 3 is a schematic cross-sectional view diagram taken along lines A-A′ and B-B′ in FIG. 2;

FIG. 4 illustrates, in a schematic top-view diagram, an intermediate semiconductor device in accordance with one embodiment of the present disclosure;

FIG. 5 is a schematic cross-sectional view diagram taken along lines A-A′ and B-B′ in FIG. 4;

FIG. 6 illustrates, in a schematic top-view diagram, an intermediate semiconductor device in accordance with one embodiment of the present disclosure;

FIGS. 7 to 9 are schematic cross-sectional view diagrams taken along the lines A-A′ and B-B′ in FIG. 6 illustrating part of a flow for fabricating the semiconductor device in accordance with one embodiment of the present disclosure;

FIG. 10 illustrates, in a schematic top-view diagram, an intermediate semiconductor device in accordance with one embodiment of the present disclosure;

FIG. 11 is a schematic cross-sectional view diagram taken along lines A-A′ and B-B′ in FIG. 10;

FIG. 12 illustrates, in a schematic top-view diagram, an intermediate semiconductor device in accordance with one embodiment of the present disclosure;

FIGS. 13 to 16 are schematic cross-sectional view diagrams taken along the lines A-A′ and B-B′ in FIG. 12 illustrating part of the flow for fabricating the semiconductor device in accordance with one embodiment of the present disclosure;

FIG. 17 illustrates, in a schematic top-view diagram, an intermediate semiconductor device in accordance with one embodiment of the present disclosure;

FIGS. 18 and 19 are schematic cross-sectional view diagrams taken along the lines A-A′ and B-B′ in FIG. 17 illustrating part of the flow for fabricating the semiconductor device in accordance with one embodiment of the present disclosure;

FIG. 20 illustrates, in a schematic top-view diagram, an intermediate semiconductor device in accordance with one embodiment of the present disclosure;

FIG. 21 is a schematic cross-sectional view diagram taken along lines A-A′ and B-B′ in FIG. 20;

FIGS. 22 to 24 illustrate, in schematic cross-sectional view diagrams, semiconductor devices in accordance with some embodiments of the present disclosure;

FIG. 25 illustrates, in a schematic top-view diagram, an intermediate semiconductor device in accordance with one embodiment of the present disclosure;

FIGS. 26 to 30 are schematic cross-sectional view diagrams taken along the lines A-A′ and B-B′ in FIG. 25 illustrating part of a flow for fabricating a semiconductor device in accordance with another embodiment of the present disclosure;

FIG. 31 illustrates, in a schematic top-view diagram, an intermediate semiconductor device in accordance with one embodiment of the present disclosure;

FIG. 32 is a schematic cross-sectional view diagram taken along lines A-A′ and B-B′ in FIG. 31;

FIG. 33 illustrates, in a schematic top-view diagram, an intermediate semiconductor device in accordance with one embodiment of the present disclosure;

FIG. 34 is a schematic cross-sectional view diagram taken along lines A-A′ and B-B′ in FIG. 33;

FIG. 35 illustrates, in a schematic top-view diagram, an intermediate semiconductor device in accordance with one embodiment of the present disclosure;

FIG. 36 is a schematic cross-sectional view diagram taken along lines A-A′ and B-B′ in FIG. 35;

FIG. 37 illustrates, in a schematic top-view diagram, an intermediate semiconductor device in accordance with one embodiment of the present disclosure; and

FIG. 38 is a schematic cross-sectional view diagram taken along lines A-A′ and B-B′ in FIG. 37.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the Z direction, and below (or down) corresponds to the opposite direction of the arrow of the Z direction.

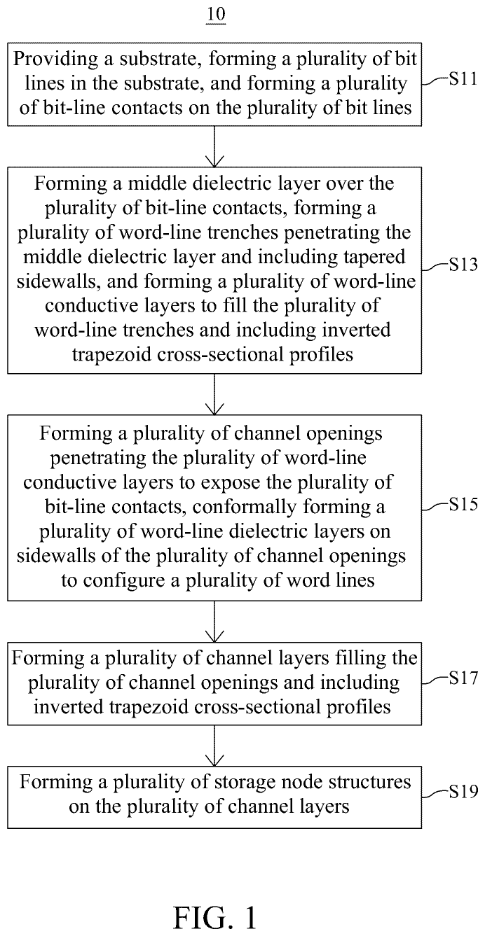

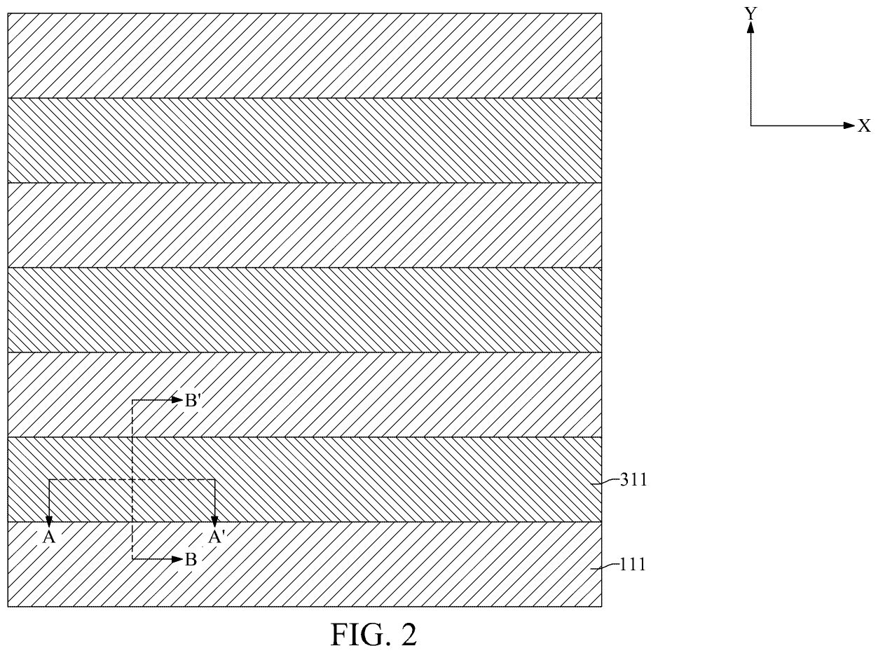

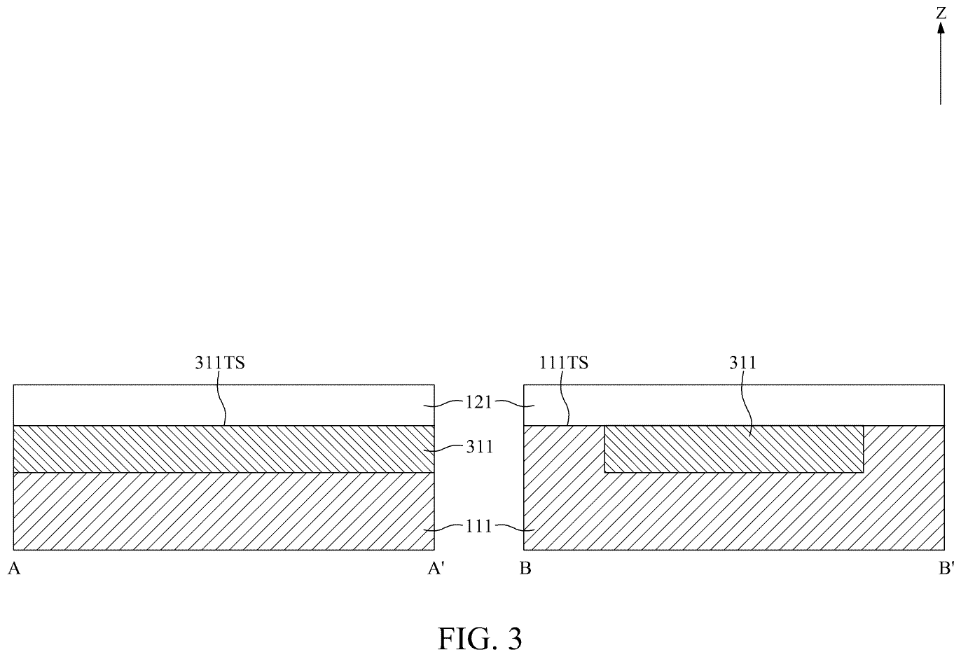

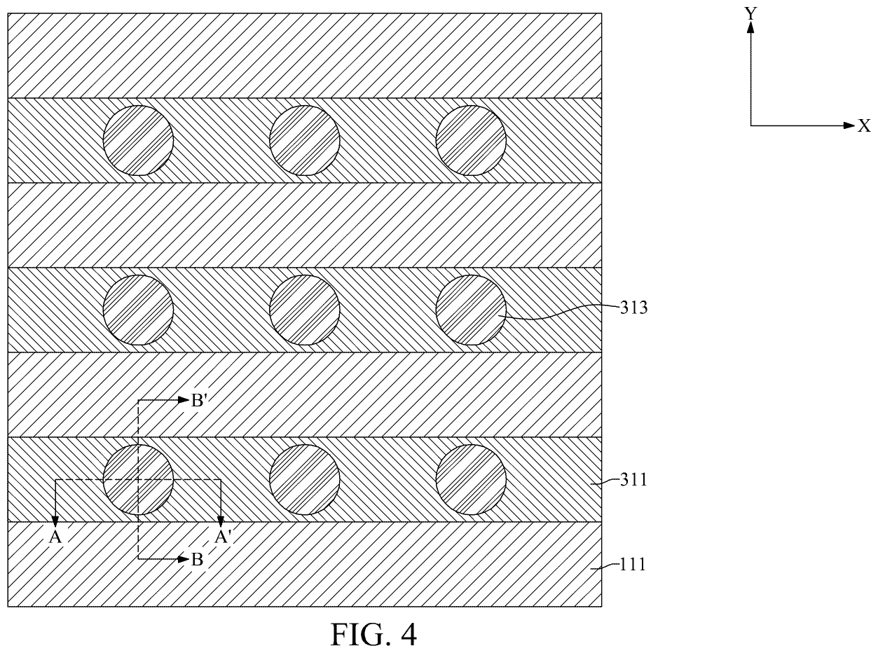

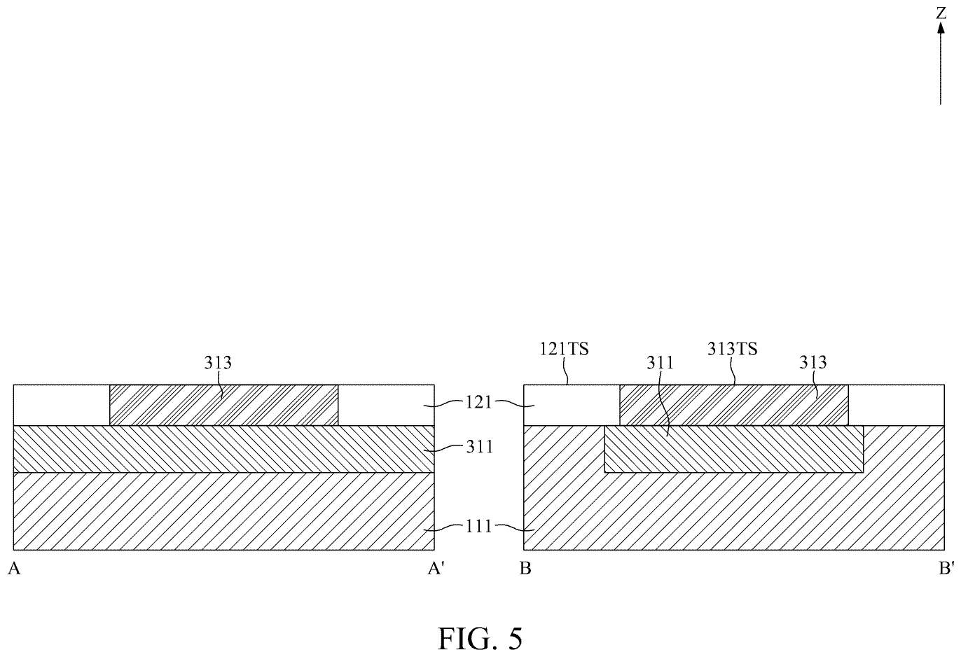

FIG. 1 illustrates, in a flowchart diagram form, a method 10 for fabricating a semiconductor device 1A in accordance with one embodiment of the present disclosure. FIG. 2 illustrates, in a schematic top-view diagram, an intermediate semiconductor device in accordance with one embodiment of the present disclosure. FIG. 3 is a schematic cross-sectional view diagram taken along lines A-A′ and B-B′ in FIG. 2. FIG. 4 illustrates, in a schematic top-view diagram, an intermediate semiconductor device in accordance with one embodiment of the present disclosure. FIG. 5 is a schematic cross-sectional view diagram taken along lines A-A′ and B-B′ in FIG. 4.

With reference to FIGS. 1 to 5, at step S11, a substrate 111 may be provided, a plurality of bit lines 311 may be formed in the substrate 111, and a plurality of bit-line contacts 313 may be formed on the plurality of bit lines 311.

With reference to FIGS. 2 and 3, the substrate 111 may include a bulk semiconductor substrate. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or combinations thereof.

In some embodiments, the substrate 111 may include a semiconductor-on-insulator structure which consists of, from bottom to top, a handle substrate, an insulator layer, and a topmost semiconductor material layer. The handle substrate and the topmost semiconductor material layer may be formed of the same material as the bulk semiconductor substrate aforementioned. The insulator layer may be a crystalline or non-crystalline dielectric material such as an oxide and/or nitride. For example, the insulator layer may be a dielectric oxide such as silicon oxide. For another example, the insulator layer may be a dielectric nitride such as silicon nitride or boron nitride. For yet another example, the insulator layer may include a stack of a dielectric oxide and a dielectric nitride such as a stack of, in any order, silicon oxide and silicon nitride or boron nitride. The insulator layer may have a thickness between about 10 nm and about 200 nm. The insulator layer may eliminate leakage current between adjacent elements in the substrate 101 and reduce parasitic capacitance associated with source/drains.

It should be noted that, the term “about” modifying the quantity of an ingredient, component, or reactant of the present disclosure employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

With reference to FIGS. 2 and 3, the plurality of bit lines 311 may be formed in the substrate 111. In a cross-sectional perspective, the top surface 311TS of the plurality of bit lines 311 and the top surface 111TS of the substrate 111 may be substantially coplanar. In a top-view perspective, the plurality of bit lines 311 may be arranged along the Y direction. Each bit line 311 may extend along the direction X.

In some embodiments, a plurality of bit-line trenches (not shown) may be formed in the substrate 111. A conductive material (not shown) may be deposited to completely fill the bit-line trenches. A planarization process, such as chemical mechanical polishing, may be performed until the top surface 111TS of the substrate 111 is exposed to remove excess material, provide a substantially flat surface for subsequent processing steps, and concurrently form the plurality of bit lines 311. In some embodiments, the conductive material may be, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

With reference to FIGS. 4 and 5, a dielectric layer 121 may be formed on the substrate 111 and cover the plurality of bit lines 311. In some embodiments, the dielectric layer 121 may be formed of, for example, silicon oxide, borophosphosilicate glass, undoped silicate glass, fluorinated silicate glass, low-k dielectric materials, the like, or a combination thereof. In some embodiments, the dielectric layer 121 may be formed by, for example, chemical vapor deposition, plasma-enhanced chemical vapor deposition, or other applicable deposition processes. It should be noted that the dielectric layer 121 is not shown in top-view diagrams for clarity. The low-k dielectric materials may have a dielectric constant less than 3.0 or even less than 2.5.

With reference to FIGS. 4 and 5, in a cross-sectional perspective, the plurality of bit-line contacts 313 may be formed penetrating the dielectric layer 121 and electrically connected to the plurality of bit lines 311. The top surface 313TS of the plurality of bit-line contacts 313 and the top surface 121TS of the dielectric layer 121 may be substantially coplanar. In a top-view perspective, the plurality of bit-line contacts 313 may include circular cross-sectional profile but is not limited thereto. The plurality of bit-line contacts 313 may be arranged along both the X direction and Y direction.

In some embodiments, a plurality of bit-line-contact openings (not shown) may be formed penetrating the dielectric layer 121 to expose the plurality of bit lines 311. A conductive material (not shown) may be deposited to completely fill the plurality of bit-line-contact openings. A planarization process, such as chemical mechanical polishing, may be performed until the top surface 121TS of the dielectric layer 121 is exposed to remove excess material, provide a substantially flat surface for subsequent processing steps, and concurrently form the plurality of bit-line contacts 313. In some embodiments, the conductive material may be, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

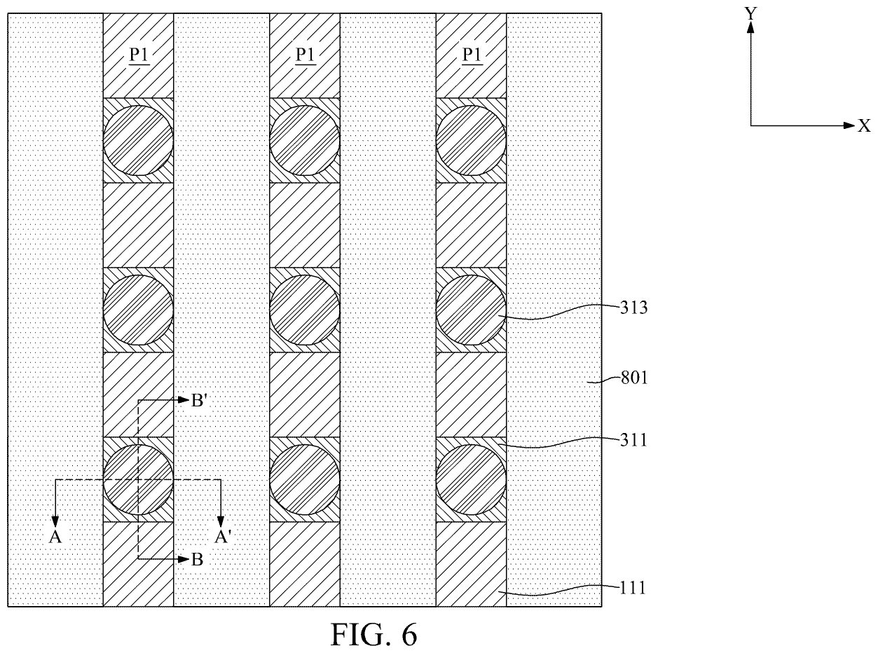

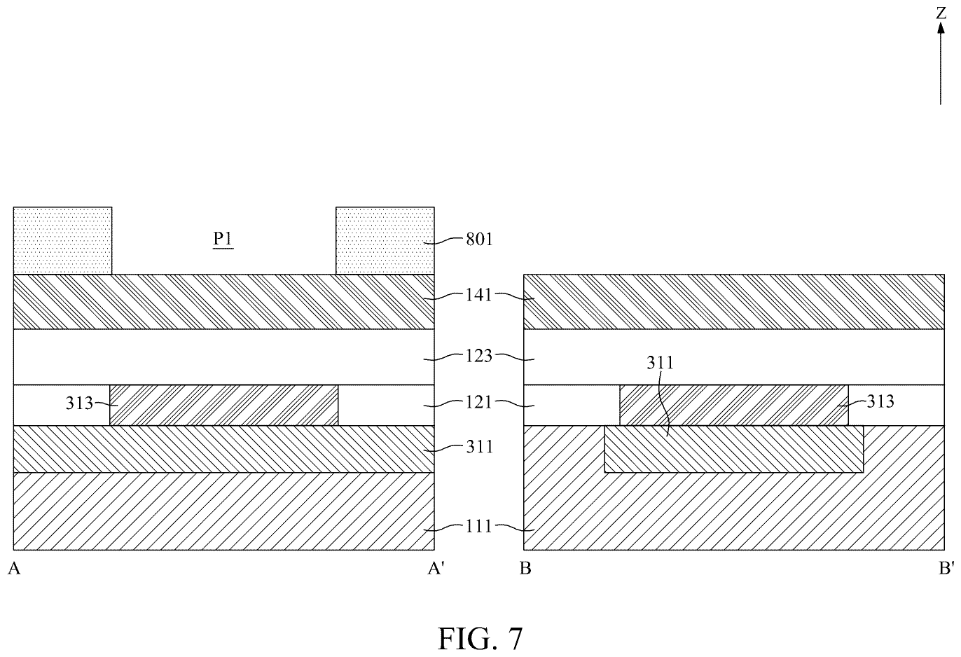

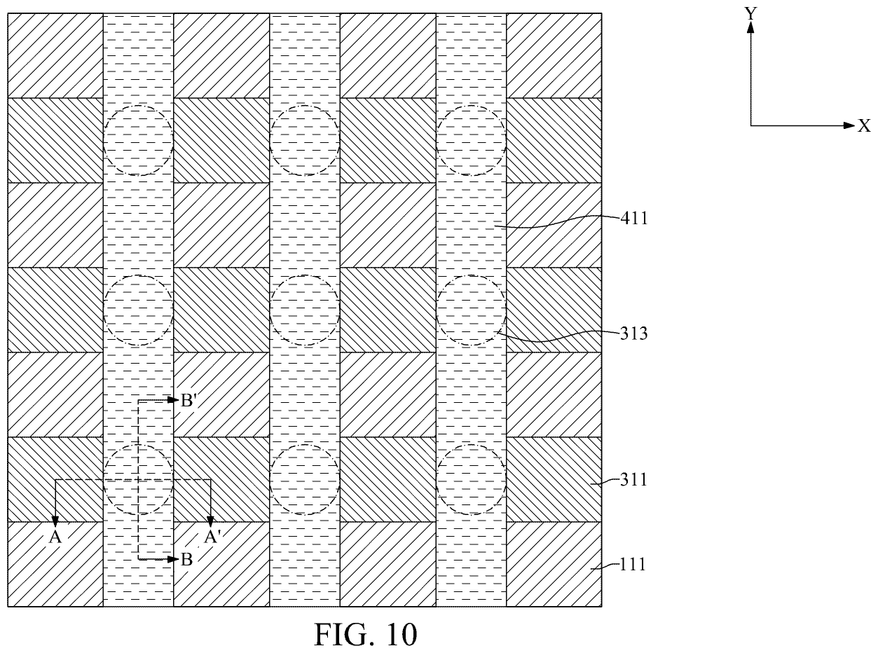

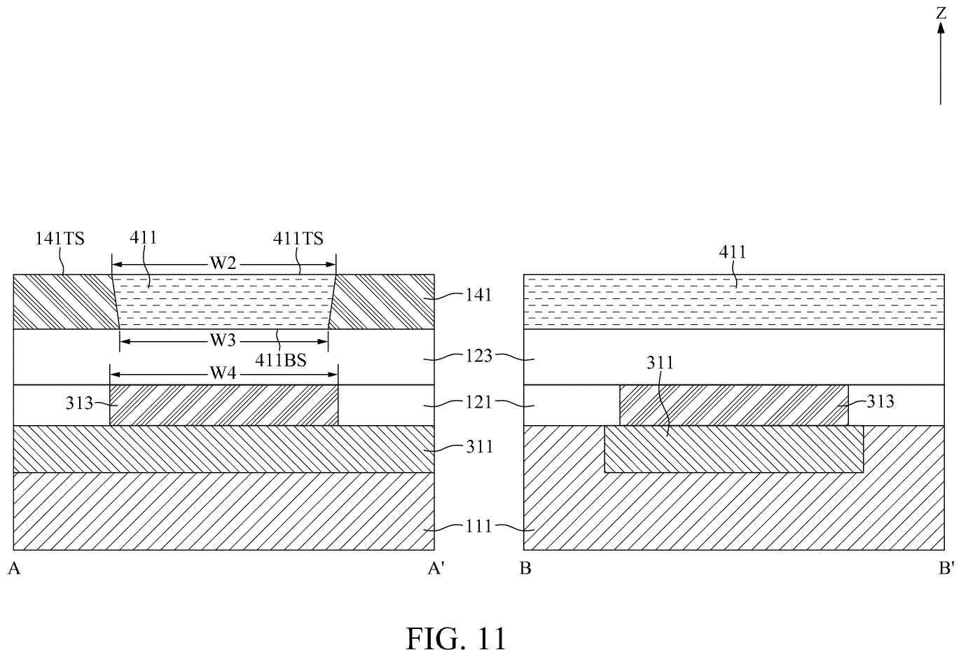

FIG. 6 illustrates, in a schematic top-view diagram, an intermediate semiconductor device in accordance with one embodiment of the present disclosure. FIGS. 7 to 9 are schematic cross-sectional view diagrams taken along the lines A-A′ and B-B′ in FIG. 6 illustrating part of a flow for fabricating the semiconductor device 1A in accordance with one embodiment of the present disclosure. FIG. 10 illustrates, in a schematic top-view diagram, an intermediate semiconductor device in accordance with one embodiment of the present disclosure. FIG. 11 is a schematic cross-sectional view diagram taken along lines A-A′ and B-B′ in FIG. 10.

With reference to FIG. 1 and FIGS. 6 to 11, at step S13, a middle dielectric layer 141 may be formed over the plurality of bit-line contacts 313, a plurality of word-line trenches TR1 may be formed penetrating the middle dielectric layer 141 and including tapered sidewalls 141SW, and a plurality of word-line conductive layers 411 may be formed to fill the plurality of word-line trenches TR1 and including inverted trapezoid cross-sectional profiles.

With reference to FIGS. 6 and 7, a dielectric layer 123 (also referred to as the lower dielectric layer 123) may be formed on the dielectric layer 121 and cover the plurality of bit-line contacts 313. In some embodiments, the dielectric layer 123 may be formed of, for example, silicon oxide, borophosphosilicate glass, undoped silicate glass, fluorinated silicate glass, low-k dielectric materials, the like, or a combination thereof. In some embodiments, the dielectric layer 123 may be formed by, for example, chemical vapor deposition, plasma-enhanced chemical vapor deposition, or other applicable deposition processes. It should be noted that the dielectric layer 123 is not shown in top-view diagrams for clarity.

With reference to FIGS. 6 and 7, the middle dielectric layer 141 may be formed on the dielectric layer 123. In some embodiments, the middle dielectric layer 141 may be formed of a material having etching selectivity to the dielectric layer 123. In some embodiments, the middle dielectric layer 141 may be formed of, for example, silicon oxide, silicon nitride, silicon carbonitride, silicon oxynitride, silicon oxycarbide, silicon oxide, boron nitride, silicon boron nitride, phosphorus boron nitride, boron carbon silicon nitride, or other applicable insulating material. In some embodiments, the middle dielectric layer 141 may be formed by, for example, chemical vapor deposition, plasma-enhanced chemical vapor deposition, or other applicable deposition processes. It should be noted that the middle dielectric layer 141 is not shown in top-view diagrams for clarity.

With reference to FIGS. 6 and 7, a first mask layer 801 may be formed on the middle dielectric layer 141. In some embodiments, the first mask layer 801 may be a photoresist layer and may include a first pattern P1. In a top-view perspective, the first pattern P1 may include a plurality of line-shaped spaces and extend along the Y direction. The middle dielectric layer 141 may be partially exposed through the first pattern P1.

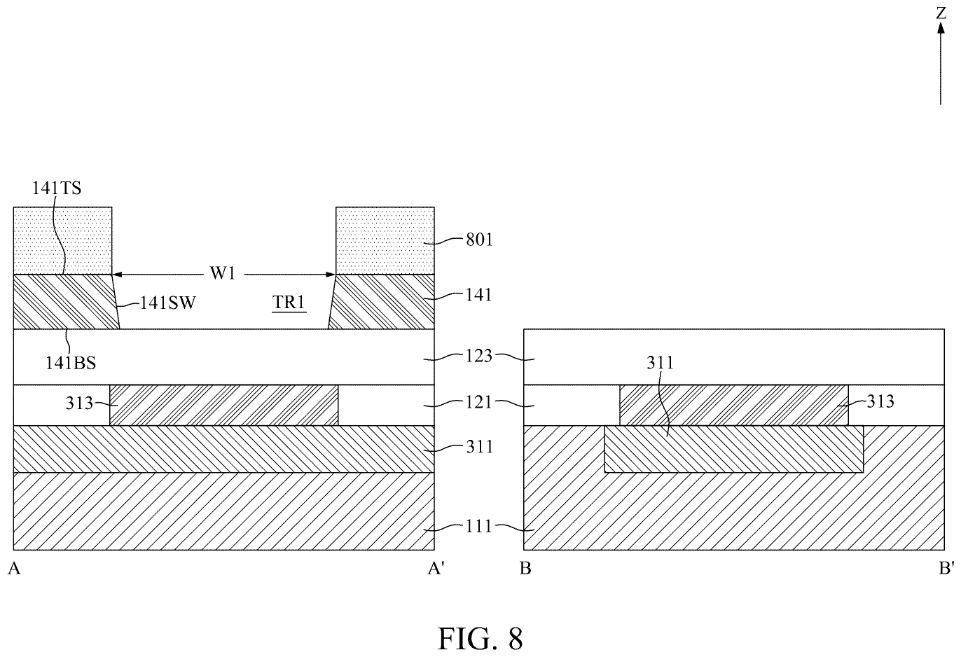

With reference to FIG. 8, an etching process (also referred to as the word-line-etching process) may be performed using the first mask layer 801 as the mask to partially remove the middle dielectric layer 141 and form the plurality of word-line trenches TR1. In some embodiments, the etching process may be an anisotropic etching process such as an anisotropic dry etching process. For brevity, clarity, and convenience of description, only one word-line trench TR1 is described.

In some embodiments, the sidewall 141 of the word-line trench TR1 may be tapered. The width (or dimension) W1 of the word-line trench TR1 may gradually decrease from the top surface 141TS of the middle dielectric layer 141 towards the bottom surface 141BS of the middle dielectric layer 141 along the opposite direction of the Z direction. State differently, the width W1 of the word-line trench TR1 near the top surface 141TS of the middle dielectric layer 141 may be greater than the width W1 of the word-line trench TR1 near the bottom surface 141BS of the middle dielectric layer 141.

After the formation of the word-line trench TR1, the first mask layer 801 may be removed.

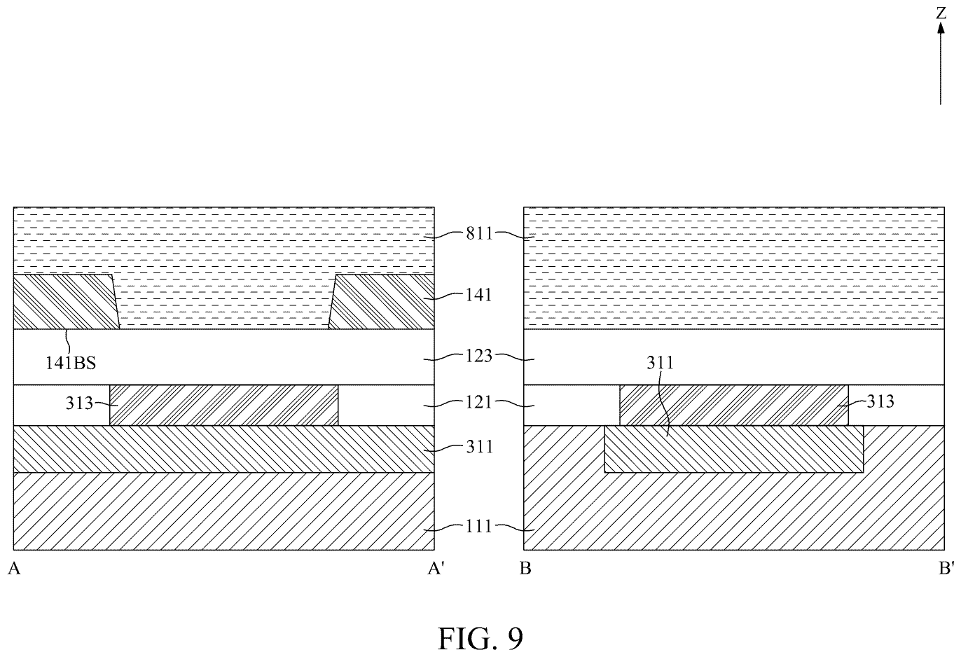

With reference to FIG. 9, a layer of first conductive material 811 may be formed to completely fill the word-line trench TR1. In some embodiments, the first conductive material 811 may be, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the layer of first conductive material 811 may be formed by, for example, physical vapor deposition, sputtering, electroplating, electroless plating, chemical vapor deposition, atomic layer deposition, or other applicable deposition processes.

With reference to FIGS. 10 and 11, a planarization process, such as chemical mechanical polishing, may be performed until the top surface 141TS of the middle dielectric layer 141 is exposed to remove excess material, provide a substantially flat surface for subsequent processing steps, and concurrently form the plurality of word-line conductive layers 411. In a top-view perspective, the plurality of word-line conductive layers 411 may be arranged along the direction X and extend along the Y direction. For brevity, clarity, and convenience of description, only one word-line conductive layer 411 is described.

In a cross-sectional perspective, the word-line conductive layer 411 may include an inverted trapezoid cross-sectional profile. The sidewall 411SW (or 141SW) of the word-line conductive layer 411 may be tapered. The width (or dimension) of the word-line conductive layer 411 may gradually decrease from the top surface 411TS of the word-line conductive layer 411 towards the bottom surface 411BS of the word-line conductive layer 411 along the opposite direction of the Z direction. That is, the width W2 of the top surface 411TS of the word-line conductive layer 411 may be greater than the width W3 of the bottom surface 411BS of the word-line conductive layer 411.

In some embodiments, the width W2 of the top surface 411TS of the word-line conductive layer 411 and the width W4 of the bit-line contact 313 may be substantially the same. In some embodiments, the width W2 of the top surface 411TS of the word-line conductive layer 411 and the width W4 of the bit-line contact 313 may be different.

In some embodiments, the width W3 of the bottom surface 411BS of the word-line conductive layer 411 and the width W4 of the bit-line contact 313 may be substantially the same. In some embodiments, the width W3 of the bottom surface 411BS of the word-line conductive layer 411 and the width W4 of the bit-line contact 313 may be different.

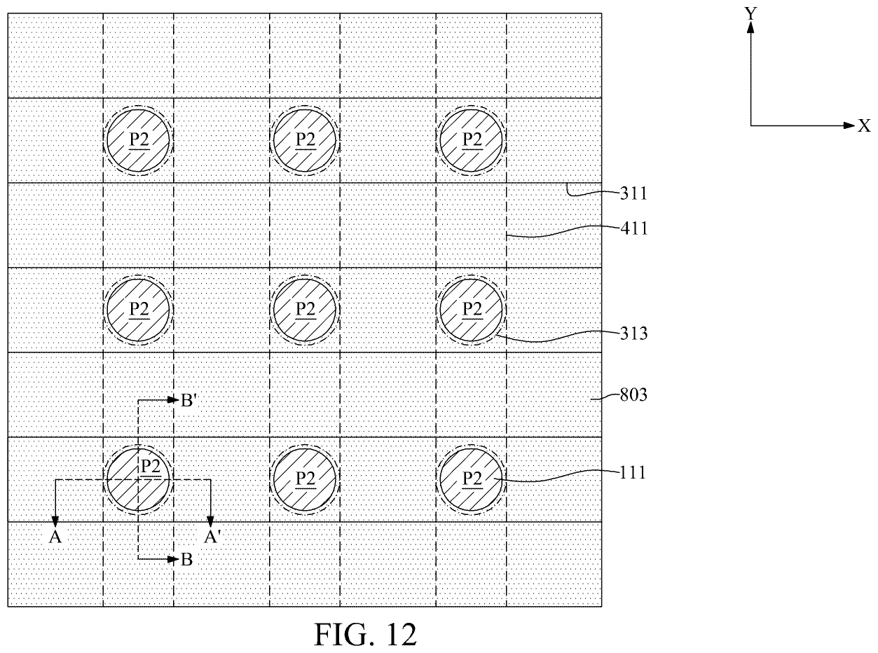

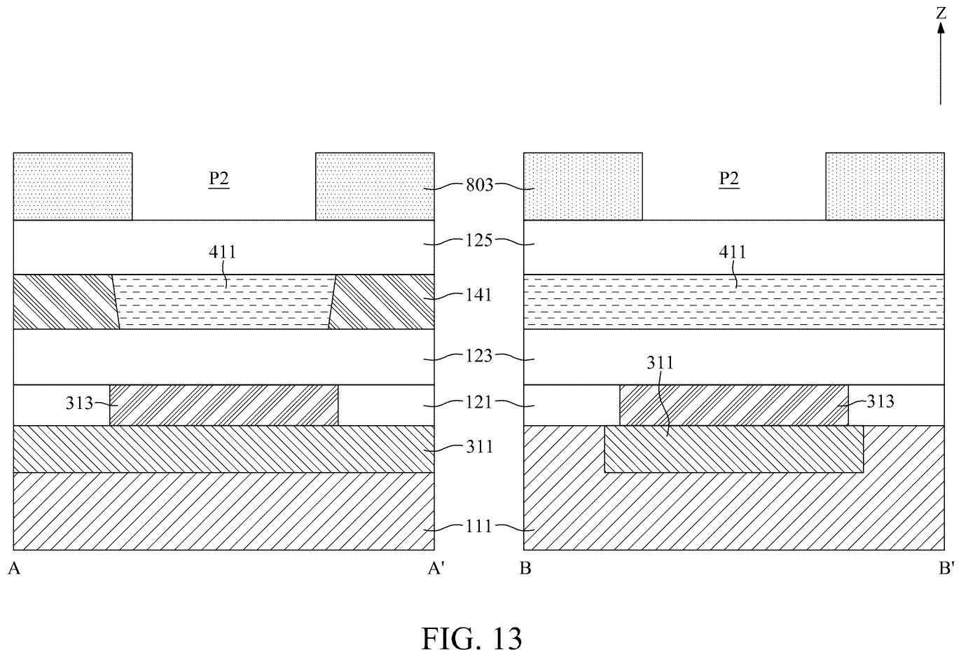

FIG. 12 illustrates, in a schematic top-view diagram, an intermediate semiconductor device in accordance with one embodiment of the present disclosure. FIGS. 13 to 16 are schematic cross-sectional view diagrams taken along the lines A-A′ and B-B′ in FIG. 12 illustrating part of the flow for fabricating the semiconductor device 1A in accordance with one embodiment of the present disclosure.

With reference to FIG. 1 and FIGS. 12 to 16, at step S15, a plurality of channel openings OP1 may be formed penetrating the plurality of word-line conductive layers 411 to expose the plurality of bit-line contacts 313, a plurality of word-line dielectric layers 413 may be conformally formed on sidewalls 413SW of the plurality of channel openings OP1 to configure a plurality of word lines 410.

With reference to FIGS. 12 and 13, a dielectric layer 125 (also referred to as the upper dielectric layer 125) may be formed on the middle dielectric layer 141 and cover the plurality of word-line conductive layers 411. In some embodiments, the dielectric layer 125 may be formed of, for example, silicon oxide, borophosphosilicate glass, undoped silicate glass, fluorinated silicate glass, low-k dielectric materials, the like, or a combination thereof. In some embodiments, the dielectric layer 125 may be formed by, for example, chemical vapor deposition, plasma-enhanced chemical vapor deposition, or other applicable deposition processes. It should be noted that the dielectric layer 125 is not shown in top-view diagrams for clarity.

With reference to FIGS. 12 and 13, a second mask layer 803 may be formed on the dielectric layer 125. In some embodiments, the second mask layer 803 may be a photoresist layer and may include a second pattern P2. In a top-view perspective, the second pattern P2 may include a plurality of circular shaped spaces which are topographically aligned with the plurality of bit-line contacts 313, respectively and correspondingly. The second pattern P2 may be at the intersections of the word-line conductive layers 411 and the plurality of bit lines 311. The dielectric layer 125 may be partially exposed through the second pattern P2.

It should be noted that in the description of the present disclosure, the term “an element A (or a feature A) is topographically aligned with an element B (or a feature B)” means that element A is directly under (or above) the element B. In a top-view perspective, the element A and the element B may be overlapped.

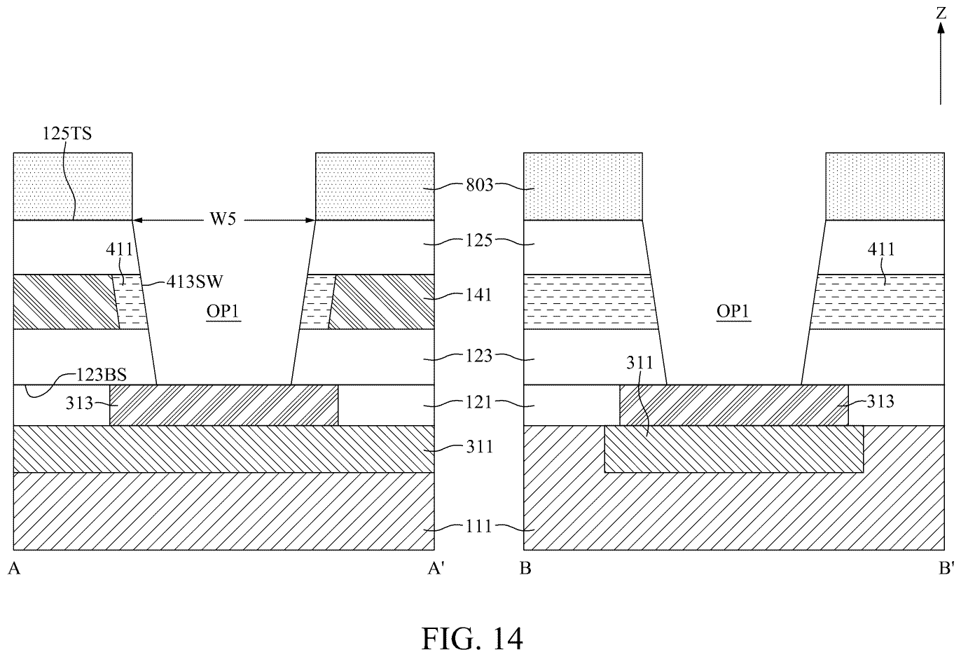

With reference to FIG. 14, an etching process (also referred to as the channel-etching process) may be performed using the second mask layer 803 as the mask to remove the dielectric layer 125, the word-line conductive layer 411, and the dielectric layer 125 and form the plurality of channel openings OP1. The plurality of bit-line contacts 313 may be exposed through the plurality of channel openings OP1. In some embodiments, the etching process may be an anisotropic etching process such as an anisotropic dry etching process. For brevity, clarity, and convenience of description, only one channel opening OP1 is described.

In some embodiments, the sidewall 413SW of the channel opening OP1 may be tapered. The width (or dimension) W5 of the channel opening OP1 may gradually decrease from the top surface 125TS of the dielectric layer 125 towards the bottom surface 123BS of the dielectric layer 123 along the opposite direction of the Z direction. State differently, the width W5 of the channel opening OP1 near the top surface 125TS of the dielectric layer 125 may be greater than the width W5 of the channel opening OP1 near the bottom surface 123BS of the dielectric layer 123.

After the formation of the channel opening OP1, the second mask layer 803 may be removed.

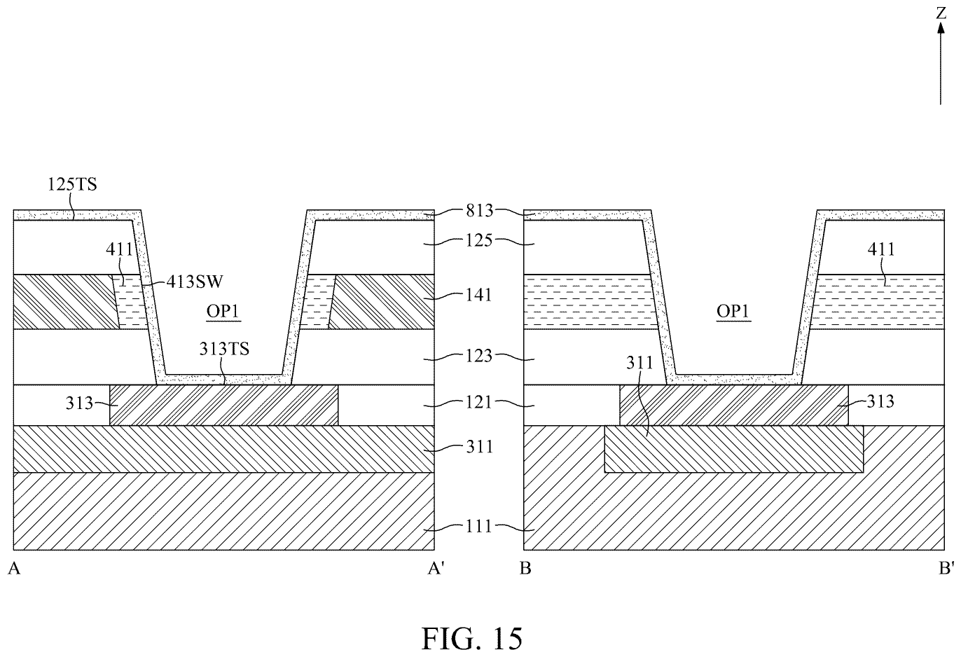

With reference to FIG. 15, a layer of first dielectric material 813 may be conformally formed on the top surface 125TS of the dielectric layer 125, sidewall 413SW of the channel opening OP1, and on the bit-line contact 313 exposed through the channel opening OP1. In some embodiments, the first dielectric material 813 may be, for example, a high-k dielectric material, silicon oxide, silicon nitride, silicon oxynitride, or a combination thereof. In some embodiments, the layer of first dielectric material 813 may be formed by, for example, atomic layer deposition or other applicable deposition processes.

In some embodiments, the high-k dielectric material may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

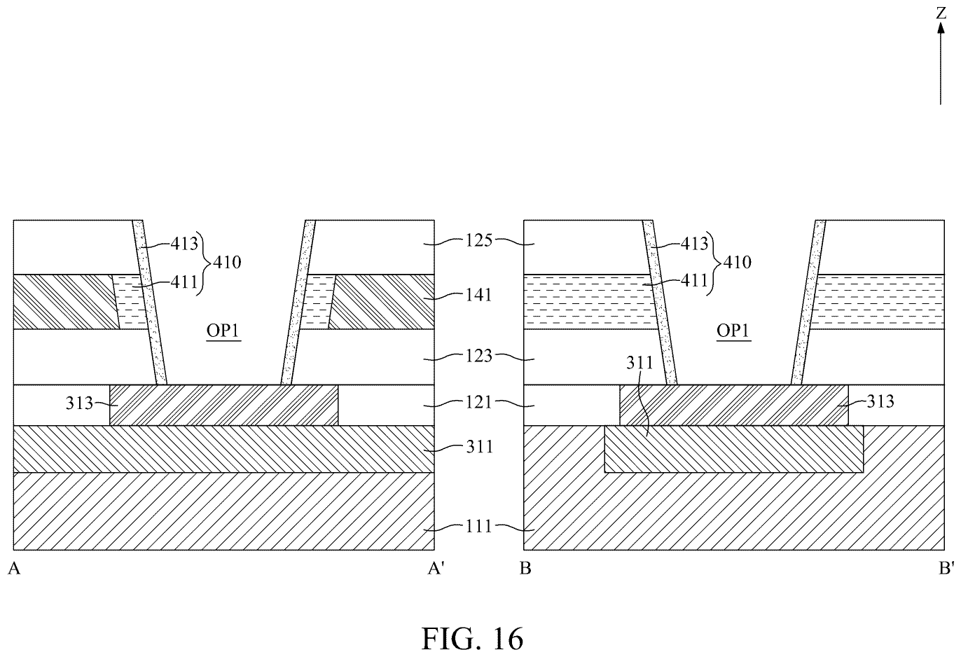

With reference to FIG. 16, a punch-etching process may be performed to remove the first dielectric material 813 formed on the top surface 125TS of the dielectric layer 125 and on the bit-line contact 313. In some embodiments, the punch-etching process may be an anisotropic etching process such as an anisotropic dry etching process. After the punch-etching process, the bit-line contact 313 may be exposed through the channel opening OP1.

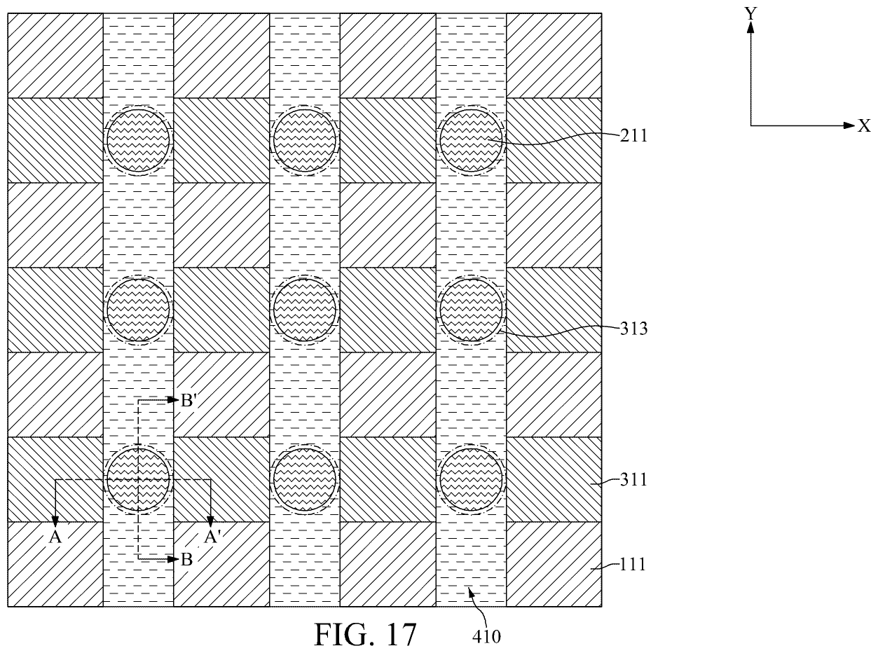

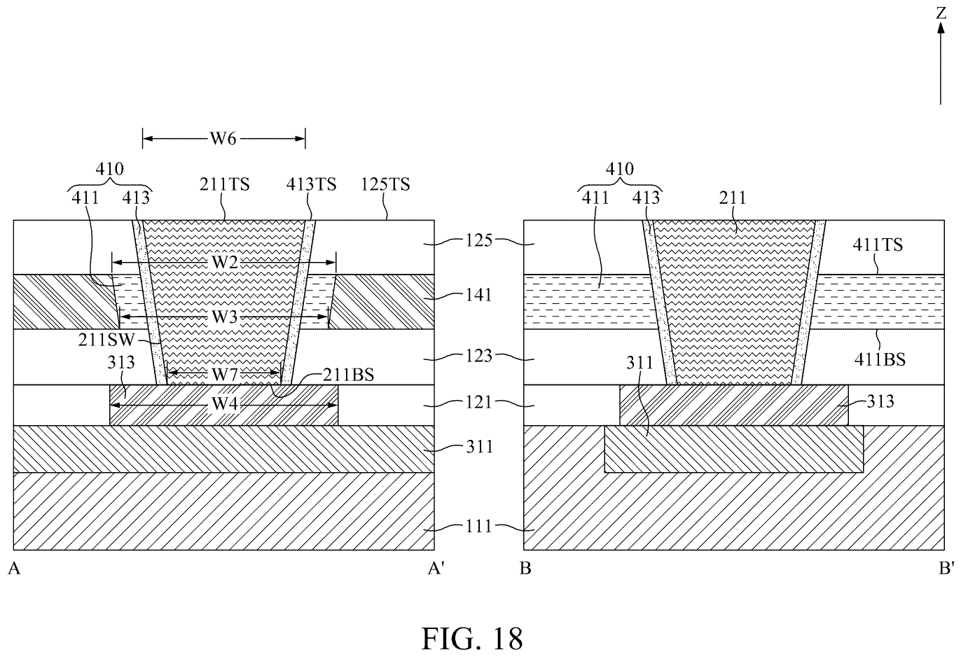

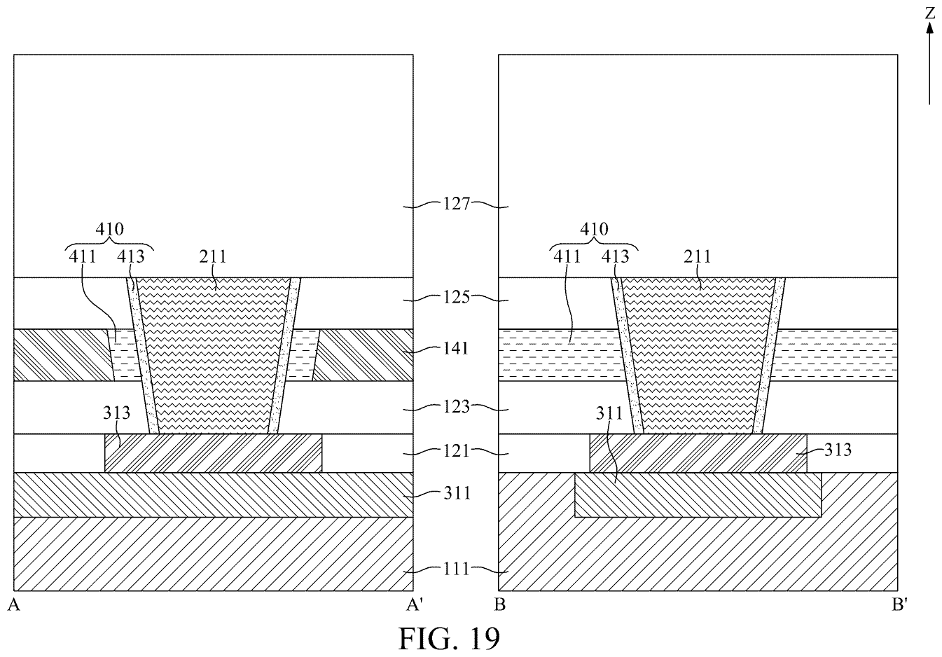

FIG. 17 illustrates, in a schematic top-view diagram, an intermediate semiconductor device in accordance with one embodiment of the present disclosure. FIGS. 18 and 19 are schematic cross-sectional view diagrams taken along the lines A-A′ and B-B′ in FIG. 17 illustrating part of a flow for fabricating the semiconductor device 1A in accordance with one embodiment of the present disclosure.

With reference to FIG. 1 and FIGS. 17 to 19, at step S17, a plurality of channel layers 211 may be formed to fill the plurality of channel openings OP1 and including inverted trapezoid cross-sectional profiles.

With reference to FIGS. 17 and 18, a conductive material (not shown) may be deposited to completely fill the o channel opening OP1. A planarization process, such as chemical mechanical polishing, may be performed until the top surface 125TS is exposed to remove excess material, provide a substantially flat surface for subsequent processing steps, and concurrently form the plurality of channel layers 211. In some embodiments, the conductive material may be, for example, doped polycrystalline silicon, doped polycrystalline germanium, or doped polycrystalline silicon germanium. In some embodiments, the conductive material may be formed by, for example, chemical vapor deposition, plasma-enhanced chemical vapor deposition, or other applicable deposition processes. For brevity, clarity, and convenience of description, only one channel layer 211 is described. The channel layer 211 may be disposed on the bit-line contact 313 and electrically connected to the bit-line contact 313. The channel layer 211 and the word-line conductive layer 411 may be electrically isolated by the word-line dielectric layer 413.

In a top-view perspective, the channel opening OP1 may be at the intersection of the word-line conductive layer 411 and the bit line 311. In a cross-sectional perspective, the top surface 125TS of the dielectric layer 125, the top surface 413TS of the word-line dielectric layer 413, and the top surface 211TS of the channel layer 211 may be substantially coplanar. The channel layer 211 may include an inverted trapezoid cross-sectional profile. The sidewall 211SW of the channel layer 211 may be tapered. The width (or dimension) of the channel layer 211 may gradually decrease from the top surface 211TS of the channel layer 211 towards the bottom surface 211BS of the channel layer 211 along the opposite direction of the Z direction. That is, the width W6 of the top surface 211TS of the channel layer 211 may be greater than the width W7 of the bottom surface 211BS of the channel layer 211.

In some embodiments, the width W6 of the top surface 211TS of the channel layer 211 may be less than the width W2 of the top surface 411TS of the word-line conductive layer 411. In some embodiments, the width W7 of the bottom surface 211BS of the channel layer 211 may be less than the width W3 of the bottom surface 411BS of the word-line conductive layer 411.

With reference to FIG. 19, a dielectric layer 127 may be formed on the dielectric layer 125 and cover the channel layer 211 and the word-line dielectric layer 413. In some embodiments, the dielectric layer 127 may be formed of, for example, silicon oxide, borophosphosilicate glass, undoped silicate glass, fluorinated silicate glass, low-k dielectric materials, the like, or a combination thereof. In some embodiments, the dielectric layer 127 may be formed by, for example, chemical vapor deposition, plasma-enhanced chemical vapor deposition, or other applicable deposition processes. It should be noted that the dielectric layer 127 is not shown in top-view diagrams for clarity.

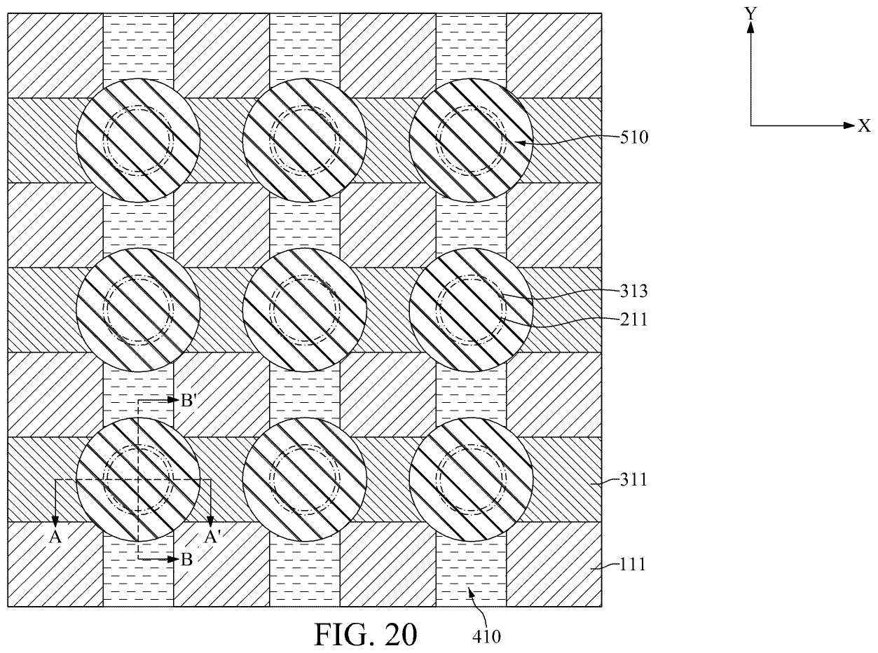

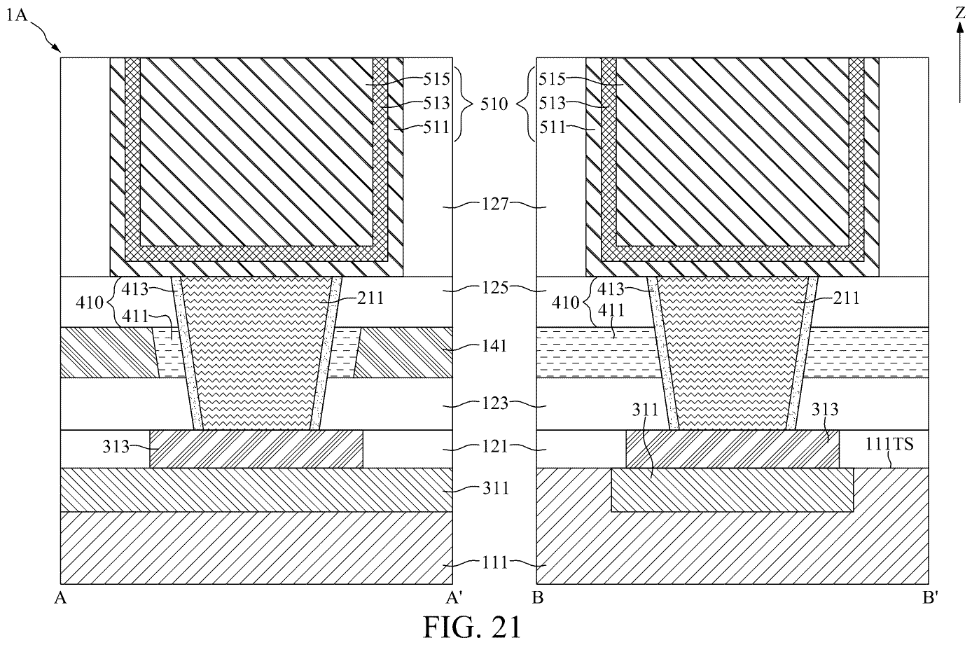

FIG. 20 illustrates, in a schematic top-view diagram, an intermediate semiconductor device in accordance with one embodiment of the present disclosure. FIG. 21 is a schematic cross-sectional view diagram taken along lines A-A′ and B-B′ in FIG. 20.

With reference to FIGS. 1, 20, and 21, at step S19, a plurality of storage node structures 510 may be formed on the plurality of channel layers 211.

For brevity, clarity, and convenience of description, only one storage node structure 510 is described.

With reference to FIGS. 20 and 21, the storage node structure 510 may be formed in the dielectric layer 127 and on the channel layer 211. The storage node structure 510 may include a first electrode layer 511, a middle insulating layer 513, and a second electrode layer 515. The first electrode layer 511 may be disposed on the channel layer 211 and include a U-shaped cross-sectional profile. In some embodiments, the first electrode layer 511 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

The middle insulating layer 513 may be disposed on the first electrode layer 511 and include a U-shaped cross-sectional profile. In some embodiments, the middle insulating layer 513 may be formed of, for example, silicon oxide, silicon nitride, a high-k dielectric material, or other applicable dielectric materials.

The second electrode layer 515 may be formed on the middle insulating layer 513. In some embodiments, the second electrode layer 515 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. The first electrode layer 511 and the second electrode layer 515 may be electrically isolated by the middle insulating layer 513.

In a top-view perspective, the storage node structure 510 may be at the intersection of the word line 410 and the bit line 311. The storage node structure 510 may be topographically aligned with the channel layer 211. State differently, the plurality of storage node structures 510 may be arranged along both the X direction and the Y direction.

By employing the word-line conductive layer 411 and the channel layer 211 with the inverted trapezoid cross-sectional profile, the process window for forming the channel layer 211 may be increased. As a result, the defect for fabricating the semiconductor device 1A may be decreased and the yield for fabricating the semiconductor device 1A may be improved.

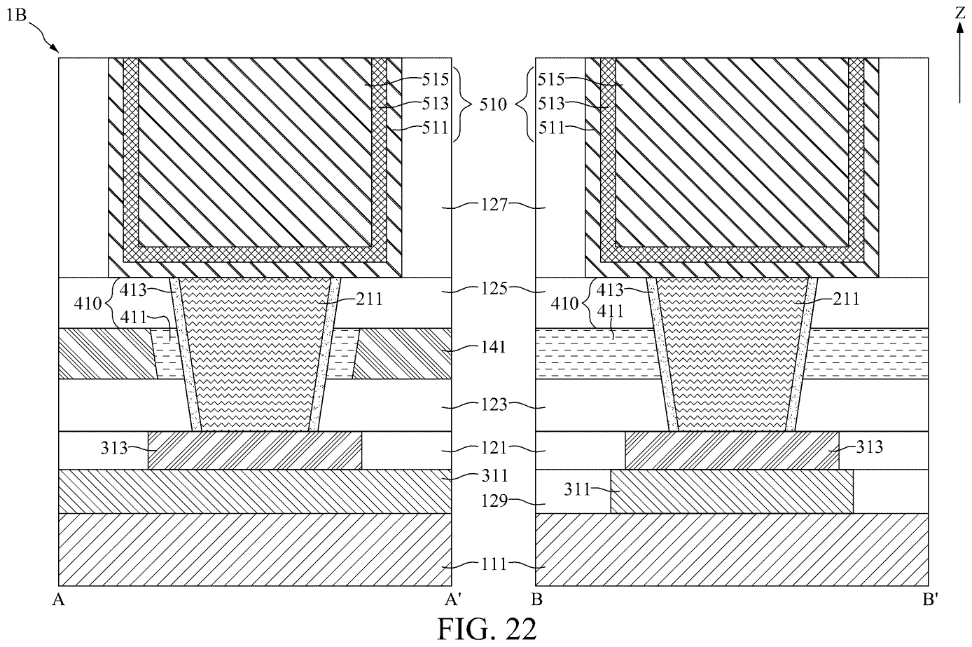

FIGS. 22 to 24 illustrate, in schematic cross-sectional view diagrams, semiconductor devices 1B, 1C, and 1D in accordance with some embodiments of the present disclosure.

With reference to FIG. 22, the semiconductor device 1B may have a structure similar to that illustrated in FIG. 21. The same or similar elements in FIG. 22 as in FIG. 21 have been marked with similar reference numbers and duplicative descriptions have been omitted.

The semiconductor device 1B may include a dielectric layer 129 disposed between the substrate 111 and the dielectric layer 123. In some embodiments, the dielectric layer 129 may be formed of, for example, silicon oxide, borophosphosilicate glass, undoped silicate glass, fluorinated silicate glass, low-k dielectric materials, the like, or a combination thereof. The bit line 311 may be disposed in the dielectric layer 129 and disposed between the bit-line contact 313 and the substrate 111.

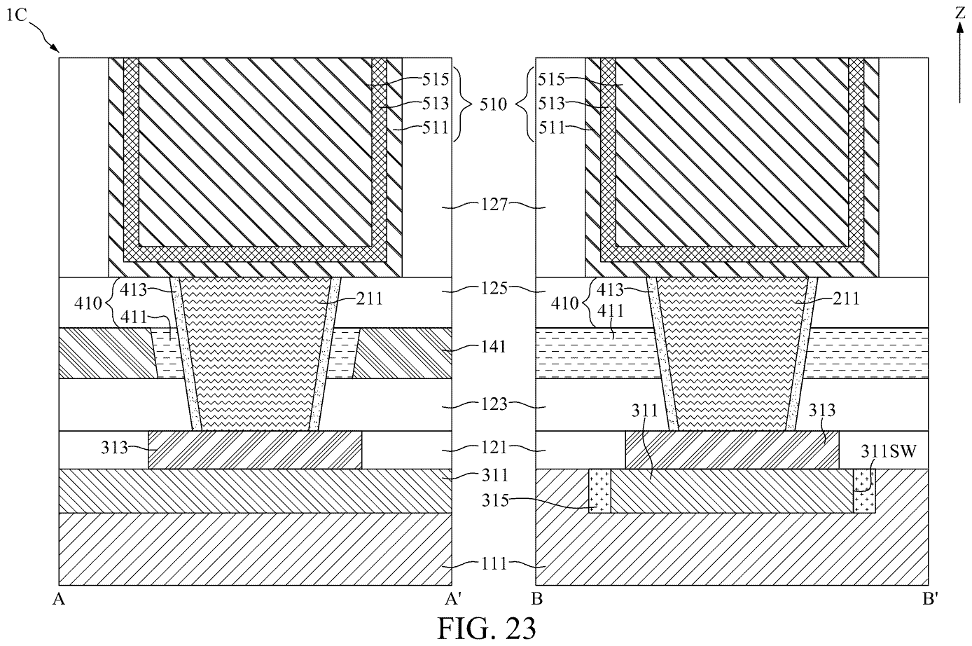

With reference to FIG. 23, the semiconductor device 1C may have a structure similar to that illustrated in FIG. 21. The same or similar elements in FIG. 23 as in FIG. 21 have been marked with similar reference numbers and duplicative descriptions have been omitted.

The semiconductor device 1C may include a plurality of bit-line spacers 315. The plurality of bit-line spacers 315 may be disposed on sidewalls 311SW of the bit line 311. In some embodiments, the plurality of bit-line spacers 315 may be porous material with low dielectric constant. In some embodiments, the plurality of bit-line spacers 315 may be air gaps. By employing the air gaps or porous spacers 315, the parasitic capacitance between adjacent bit lines 311 may be decreased. As a result, the performance of the semiconductor device 1C may be improved.

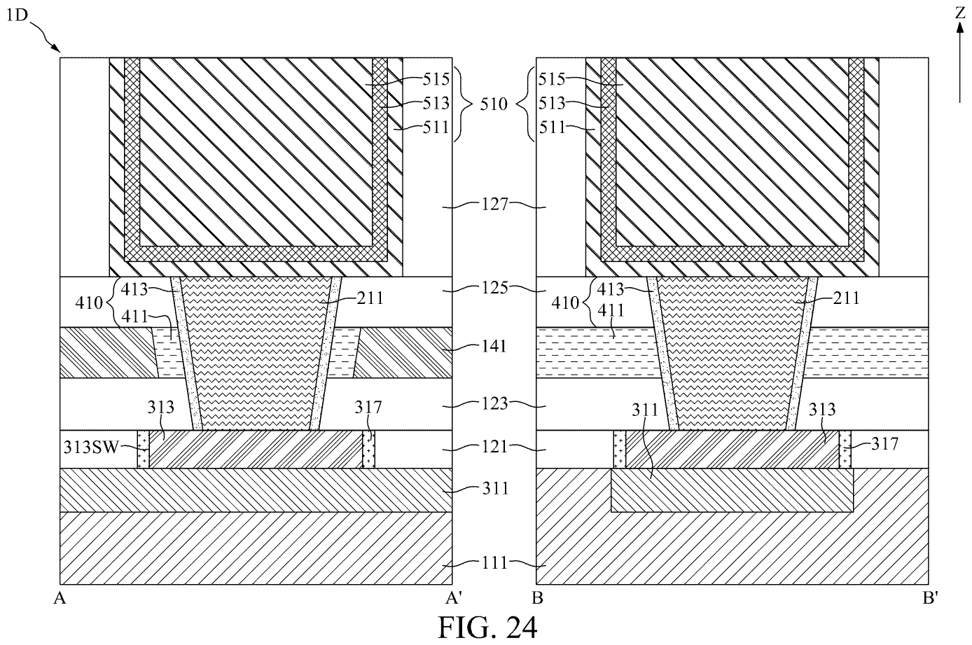

With reference to FIG. 24, the semiconductor device 1D may have a structure similar to that illustrated in FIG. 21. The same or similar elements in FIG. 24 as in FIG. 21 have been marked with similar reference numbers and duplicative descriptions have been omitted.

The semiconductor device 1D may include a plurality of bit-line-contact spacers 317. The plurality of bit-line-contact spacers 317 may be disposed on sidewalls 313SW of the bit-line contact 313. In some embodiments, the plurality of bit-line-contact spacers 317 may be porous material with low dielectric constant. In some embodiments, the plurality of bit-line-contact spacers 317 may be air gaps. By employing the air gaps or porous spacers 317, the parasitic capacitance between adjacent bit-line contacts 313 may be decreased. As a result, the performance of the semiconductor device 1D may be improved.

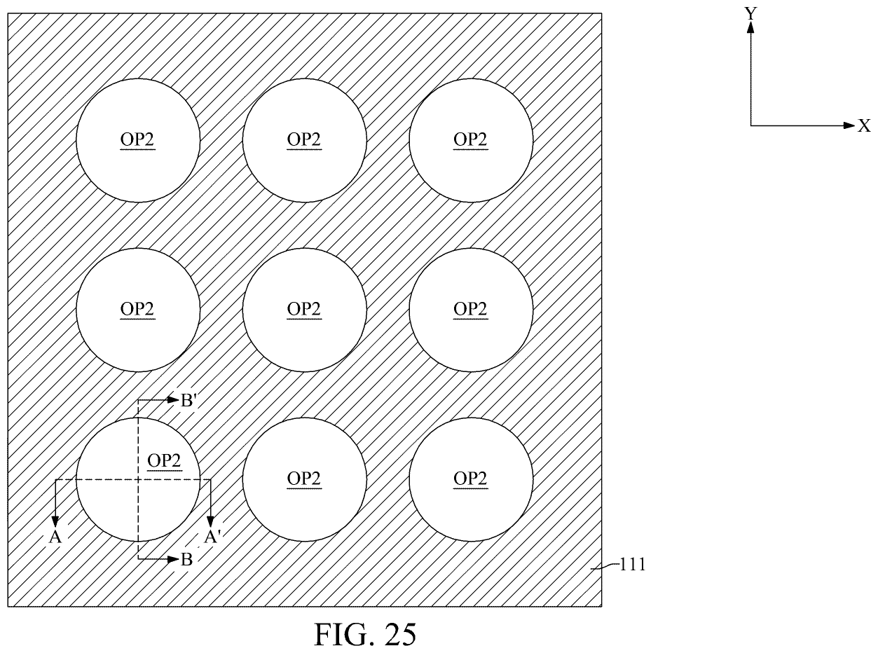

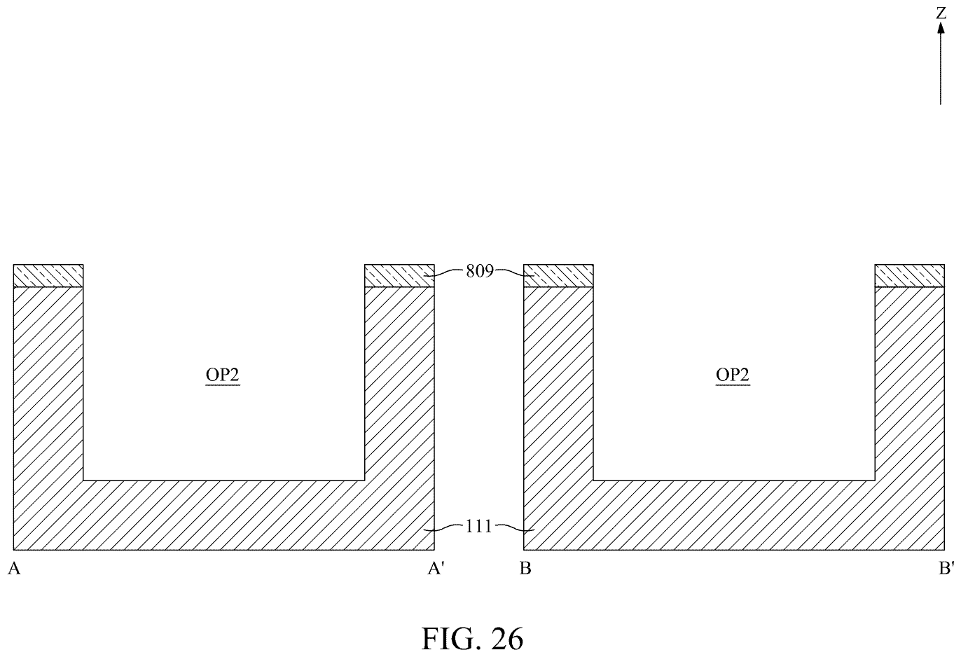

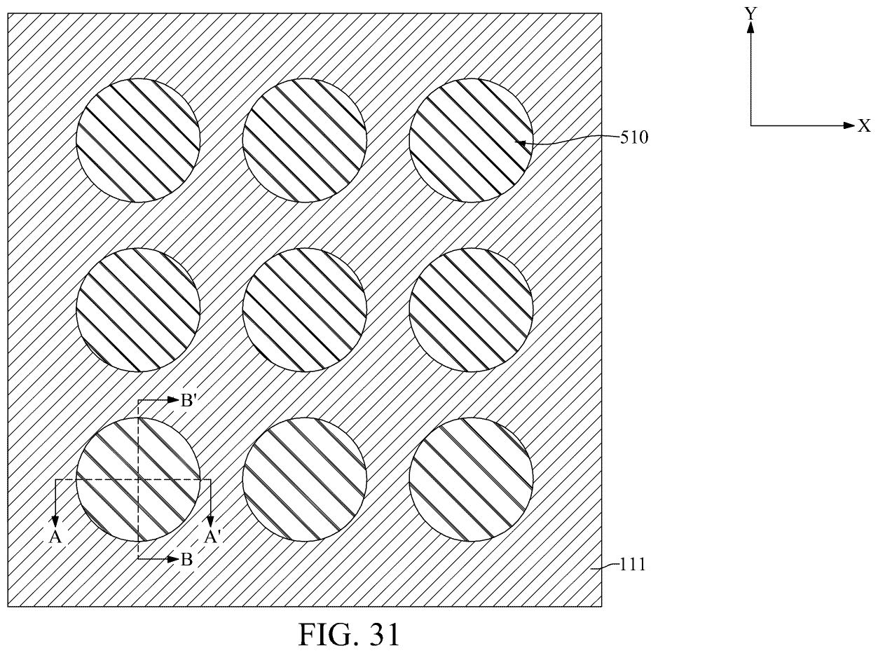

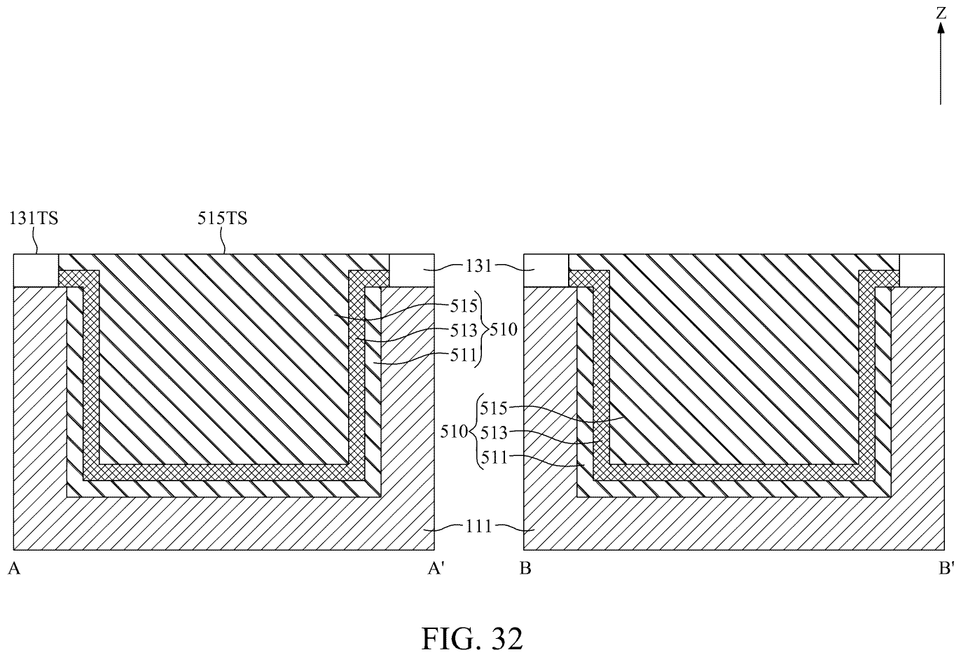

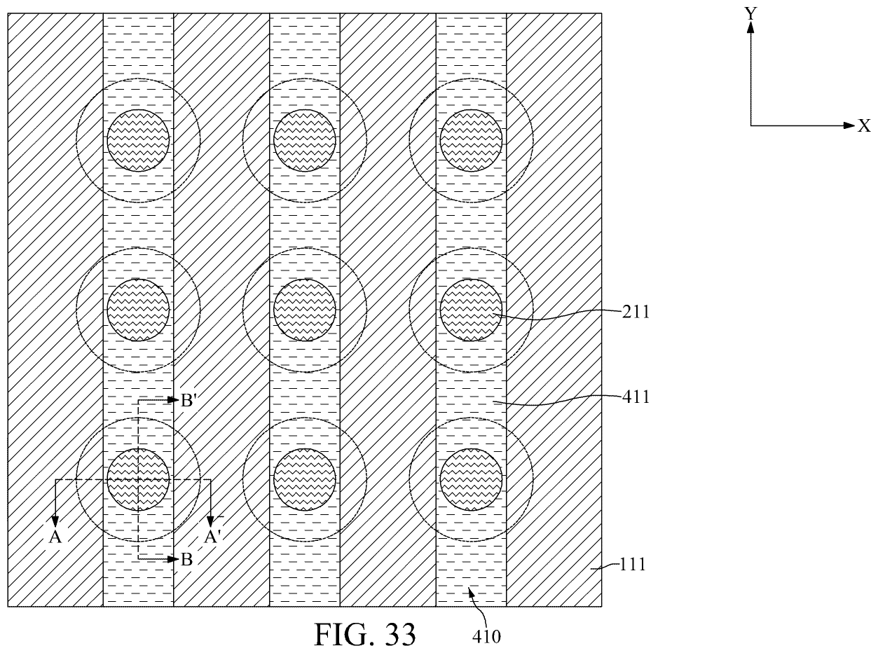

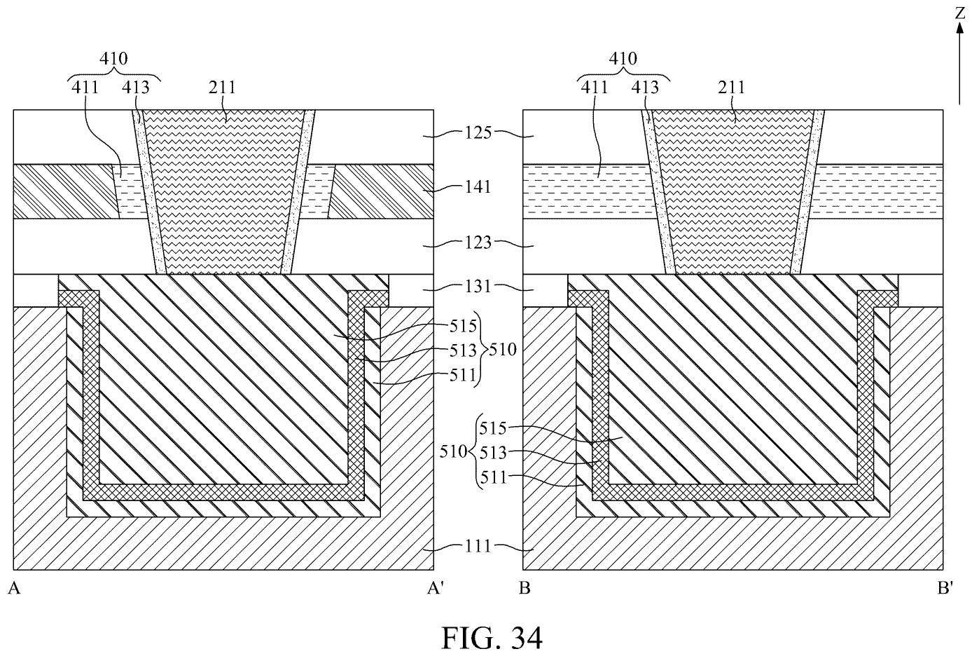

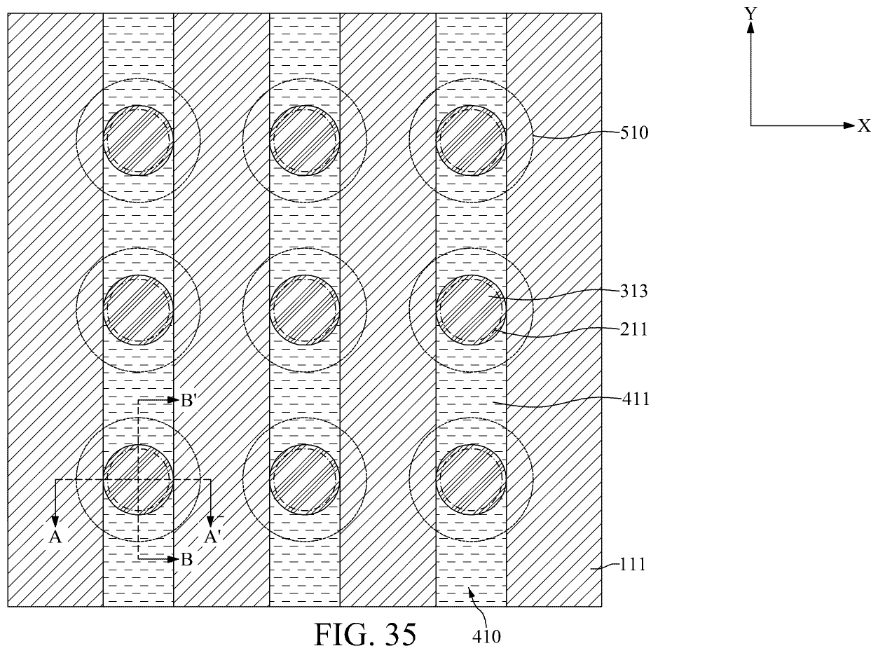

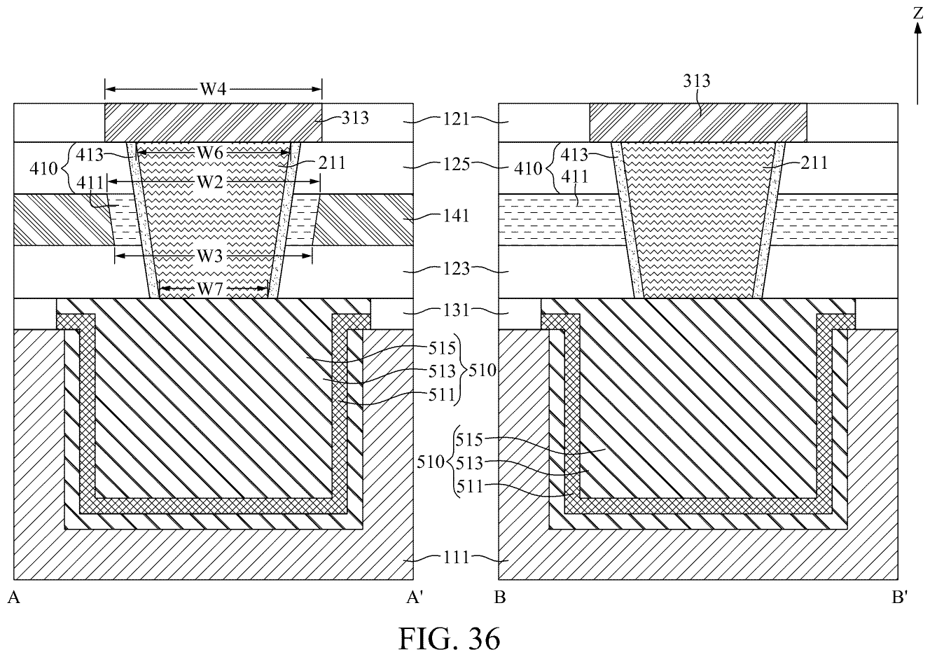

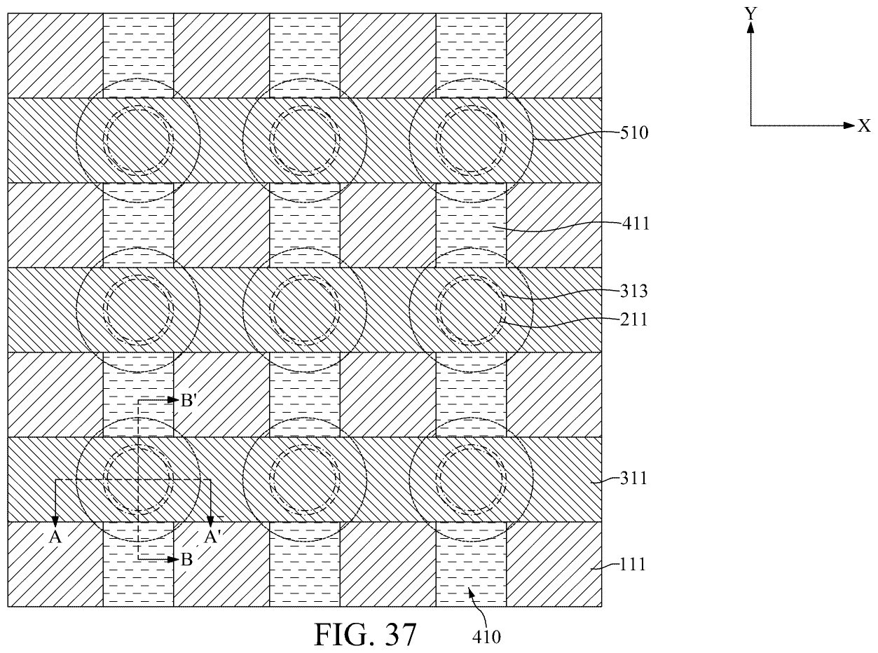

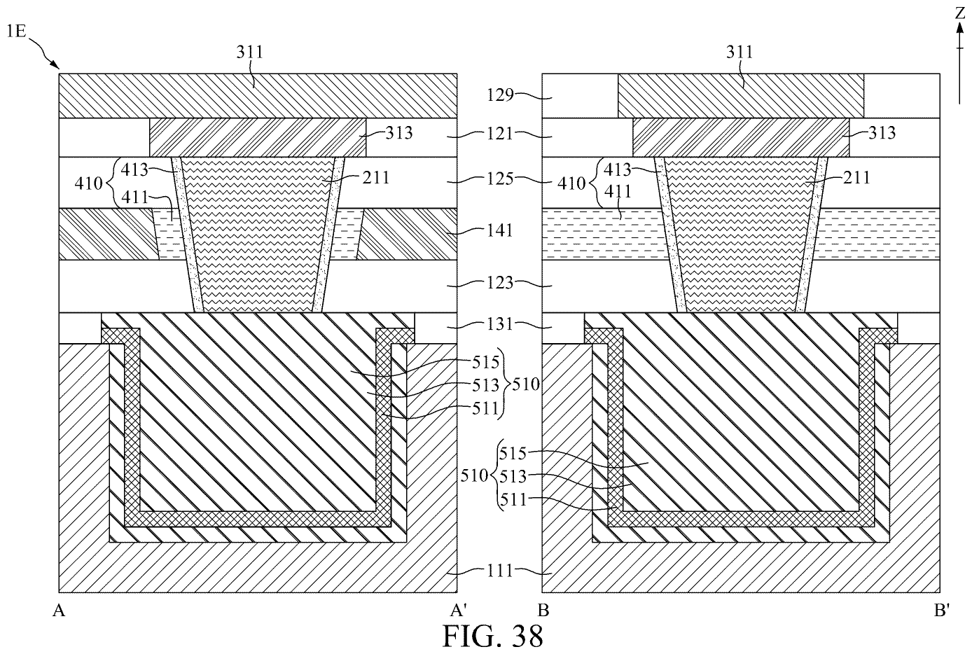

FIG. 25 illustrates, in a schematic top-view diagram, an intermediate semiconductor device in accordance with one embodiment of the present disclosure. FIGS. 26 to 30 are schematic cross-sectional view diagrams taken along the lines A-A′ and B-B′ in FIG. 25 illustrating part of a flow for fabricating a semiconductor device 1E in accordance with another embodiment of the present disclosure. FIG. 31 illustrates, in a schematic top-view diagram, an intermediate semiconductor device in accordance with one embodiment of the present disclosure. FIG. 32 is a schematic cross-sectional view diagram taken along lines A-A′ and B-B′ in FIG. 31. FIG. 33 illustrates, in a schematic top-view diagram, an intermediate semiconductor device in accordance with one embodiment of the present disclosure. FIG. 34 is a schematic cross-sectional view diagram taken along lines A-A′ and B-B′ in FIG. 33. FIG. 35 illustrates, in a schematic top-view diagram, an intermediate semiconductor device in accordance with one embodiment of the present disclosure. FIG. 36 is a schematic cross-sectional view diagram taken along lines A-A′ and B-B′ in FIG. 35. FIG. 37 illustrates, in a schematic top-view diagram, an intermediate semiconductor device in accordance with one embodiment of the present disclosure. FIG. 38 is a schematic cross-sectional view diagram taken along lines A-A′ and B-B′ in FIG. 37.

With reference to FIGS. 25 and 26, a substrate 111 may be provided with a procedure similar to that illustrated in FIG. 3, and descriptions thereof are not repeated herein. A first hard mask layer 809 may be formed on the substrate 111. In some embodiments, the first hard mask layer 809 may be formed of, for example, silicon oxide, silicon nitride, silicon oxynitride, silicon nitride oxide, boron nitride, silicon boron nitride, phosphorus boron nitride, or boron carbon silicon nitride. In some embodiments, the first hard mask layer 809 may be formed by, for example, chemical vapor deposition, atomic layer deposition, or other applicable deposition processes. It should be noted that the first hard mask layer 809 is not shown in top-view diagrams for clarity.

With reference to FIGS. 25 and 26, a plurality of storage-node openings OP2 may be formed penetrating the first hard mask layer 809 and extending to the substrate 111. In a top-view perspective, the storage-node openings OP2 may be arranged along both the X direction and the Y direction. For brevity, clarity, and convenience of description, only one storage-node opening OP2 is described.

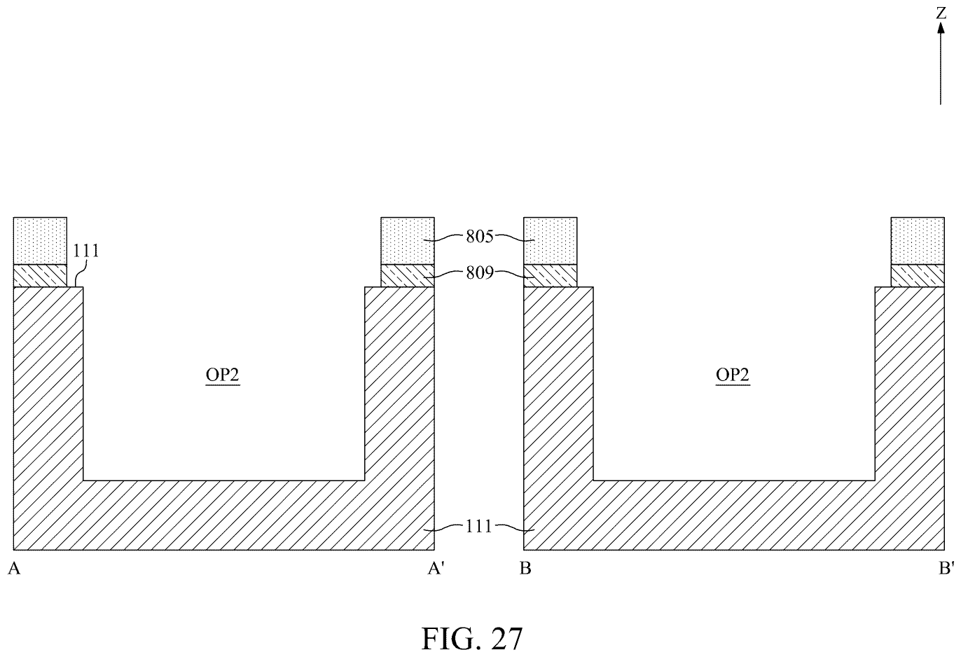

With reference to FIG. 27, a third mask layer 805 may be formed on the first hard mask layer 809. The third mask layer 805 may be a photoresist layer. Some portions of the first hard mask layer 809 may be exposed through the pattern of the third mask layer 805. For example, the portion of the first hard mask layer 809 adjacent to the storage-node opening OP2 may not be covered by the third mask layer 805. Subsequently, an etching process, such as wet etch process, may be performed to remove the exposed portions of the first hard mask layer 809. The top surface 111TS of the substrate 111 adjacent to the storage-node opening OP2 may be exposed after the removal of the first hard mask layer 809. The third mask layer 805 may be removed after the etching process.

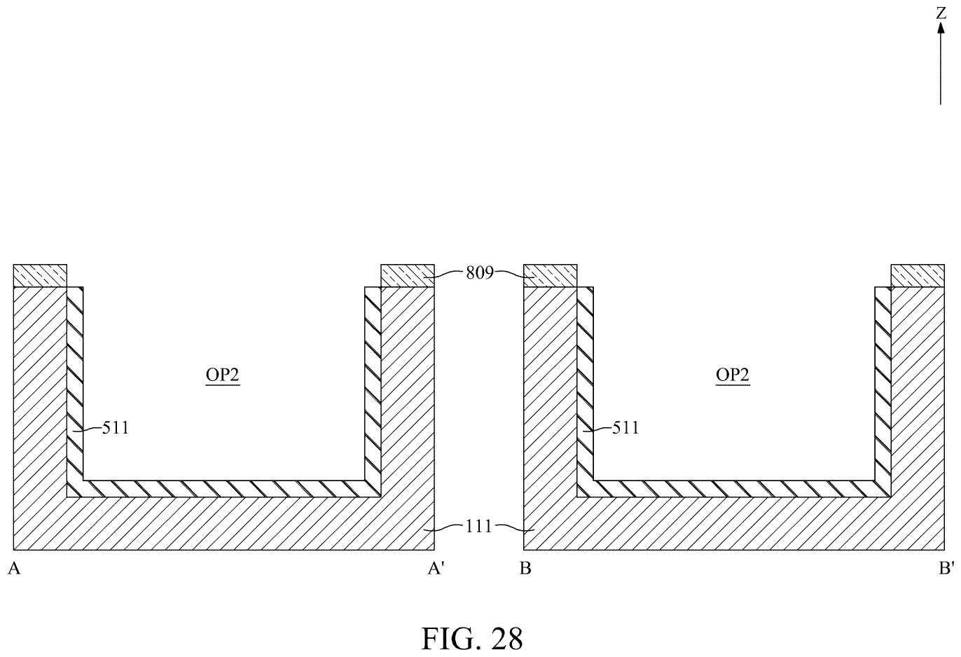

With reference to FIG. 28, an implantation process may be performed to dope the exposed region (through the storage-node opening OP2) of the substrate 111 and turn that region the first electrode layer 511. In some embodiments, the dopant of the implantation process may be, for example, phosphorus, arsenic, antimony, or boron. The first hard mask layer 809 may be removed after the formation of the first electrode layer 511.

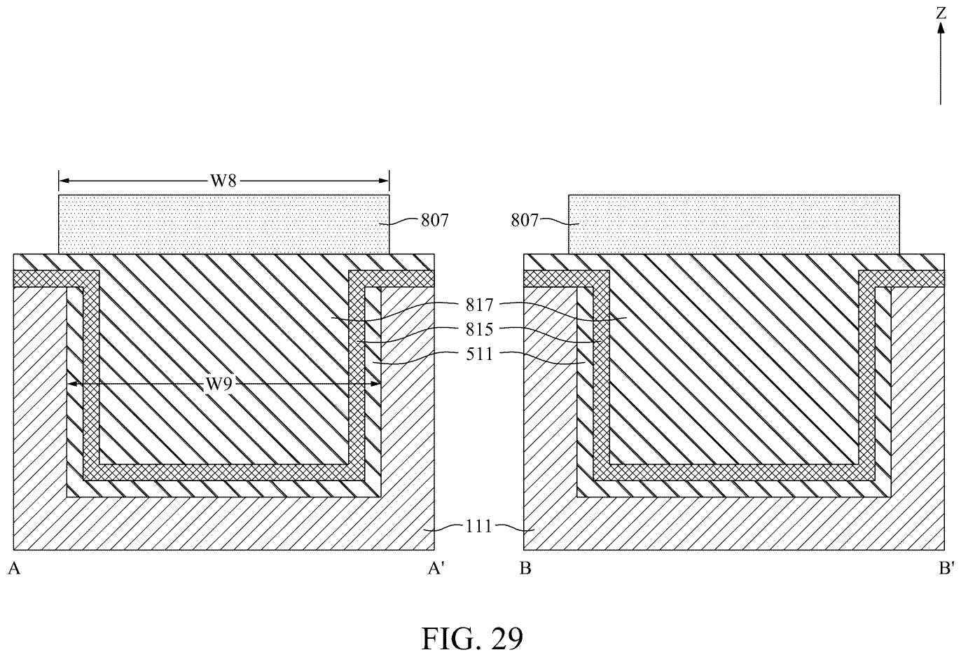

With reference to FIG. 29, a layer of first insulating material 815 may be conformally formed to cover the substrate 111 and the first electrode layer 511. In some embodiments, the layer of first insulating material 815 may have a thickness between about 10 angstroms and about 1000 angstroms. In some embodiments, the layer of first insulating material 815 may be formed by low pressure chemical vapor deposition, plasma-enhanced chemical vapor deposition, atomic layer deposition, or other applicable deposition processes.

In some embodiments, the layer of first insulating material 815 may be a stacked layer structure such as an oxide-nitride-oxide structure. In some embodiments, the first insulating material 815 may include, for example, silicon oxide, silicon nitride, silicon oxynitride, silicon nitride oxide, or the like.

In some embodiments, the first insulating material 815 may include, for example, a high-k dielectric material such as metal oxide, metal nitride, metal silicate, transition metal-oxide, transition metal-nitride, transition metal-silicate, oxynitride of metal, metal aluminate, zirconium silicate, zirconium aluminate, or a combination thereof. In some embodiments, the first insulating material 815 may be formed of hafnium oxide, hafnium silicon oxide, hafnium silicon oxynitride, hafnium tantalum oxide, hafnium titanium oxide, hafnium zirconium oxide, hafnium lanthanum oxide, lanthanum oxide, zirconium oxide, titanium oxide, tantalum oxide, yttrium oxide, strontium titanium oxide, barium titanium oxide, barium zirconium oxide, lanthanum silicon oxide, aluminum silicon oxide, aluminum oxide, silicon nitride, silicon oxynitride, silicon nitride oxide, or a combination thereof. In some embodiments, the layer of first insulating material 815 may be a stacked layer structure that includes, for example, one layer of silicon oxide and another layer of high-k dielectric material.

With reference to FIG. 29, a layer of second conductive material 817 may be formed to fill the storage-node opening OP2 and cover the layer of first insulating material 815. A planarization process, such as chemical mechanical polishing, may be performed to provide a substantially flat surface for subsequent processing steps.

In some embodiments, the second conductive material 817 may include, for example, doped polycrystalline silicon, doped polycrystalline silicon germanium, aluminum, copper, platinum, gold, titanium, titanium nitride, tantalum, tantalum nitride, tungsten, tungsten nitride, or alloy of gold and copper.

In some embodiments, the second conductive material 817 may include, for example, a material from the class containing metal borides, metal phosphides, and metal antimonides of the transition metals from the secondary groups IV, V and VI of the periodic table. The transition metals may be titanium, zirconium, hafnium, vanadium, niobium, tantalum, chromium, molybdenum, or tungsten. In some embodiments, the second conductive material 817 may include titanium diboride, zirconium diboride, hafnium diboride, titanium phosphide, zirconium phosphide, hafnium phosphide, titanium antimonide, zirconium antimonide, or hafnium antimonide. The second conductive material 817 may have a high thermal stability and excellent conductivity.

With reference to FIG. 29, a fourth mask layer 807 may be formed on the layer of second conductive material 817. The fourth mask layer 807 may be a photoresist layer. The width W8 of the fourth mask layer 807 may be greater than the width W9 of the first electrode layer 511.

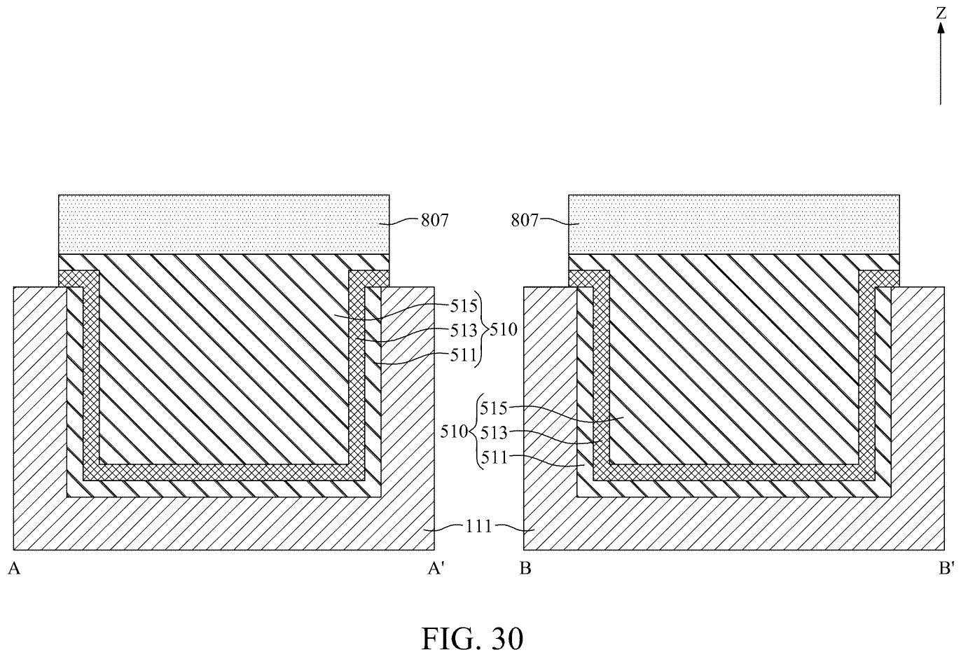

With reference to FIG. 30, an etching process, such as an anisotropic dry etch process, may be performed to remove portions of the second conductive material 817 and first insulating material 815. After the etching process, the remaining second conductive material 817 may be referred to as the second electrode layer 515. The remaining first insulating material 815 may be referred to as the 1 middle insulating layer 513. The first electrode layer 511 and the second electrode layer 515 may be electrically isolated by the middle insulating layer 513. The first electrode layer 511, the middle insulating layer 513, and the second electrode layer 515 together configure the storage node structure 510. After the formation of the storage node structure 510, the fourth mask layer 807 may be removed.

With reference to FIGS. 31 and 32, a dielectric layer 131 may be formed over the substrate 111. A planarization process, such as chemical mechanical polishing, may be subsequently performed until the top surface 515TS of the second electrode layer 515 is exposed to remove excess material and provide a substantially flat surface for subsequent processing steps. The top surface 515TS of the second electrode layer 515 and the top surface 131TS of the dielectric layer 131 may be substantially coplanar. In some embodiments, the dielectric layer 131 may be formed of, for example, silicon oxide, borophosphosilicate glass, undoped silicate glass, fluorinated silicate glass, low-k dielectric materials, the like, or a combination thereof. In some embodiments, the dielectric layer 131 may be formed by, for example, chemical vapor deposition, plasma-enhanced chemical vapor deposition, or other applicable deposition processes. It should be noted that the dielectric layer 131 is not shown in top-view diagrams for clarity.

In a top-view perspective, the plurality of storage node structures 510 may be arranged along both the X direction and the Y direction.

With reference to FIGS. 33 and 34, the dielectric layer 123 may be formed on the dielectric layer 131 and cover the storage node structure 510 with a procedure similar to that illustrated in FIGS. 6 and 7, and descriptions thereof are not repeated herein. The middle dielectric layer 141 may be formed on the dielectric layer 123 with a procedure similar to that illustrated in FIGS. 6 and 7, and descriptions thereof are not repeated herein.

With reference to FIGS. 33 and 34, the word-line conductive layer 411 may be formed in the middle dielectric layer 141 with a procedure similar to that illustrated in FIGS. 8 to 11, and descriptions thereof are not repeated herein. The channel opening OP1 (not shown) may be formed to expose the storage node structure 510 with a procedure similar to that illustrated in FIGS. 12 to 14, and descriptions thereof are not repeated herein. The word-line dielectric layer 413 and the channel layer 211 may be formed in the channel opening OP1 with a procedure similar to that illustrated in FIGS. 15 to 18, and descriptions thereof are not repeated herein. The word-line conductive layer 411 and the word-line dielectric layer 413 together configure the word line 410.

With reference to FIGS. 33 and 34, in a cross-sectional perspective, the channel layer 211 may be disposed on the storage node structure 510. In a top-view perspective, the word line 410 may be topographically aligned with the storage node structure 510. The channel layer 211 may be topographically aligned with the storage node structure 510.

With reference to FIGS. 35 and 36, the dielectric layer 121 may be formed on the dielectric layer 125 and cover the word-line dielectric layer 413 and the channel layer 211 with a procedure similar to that illustrated in FIG. 3, and descriptions thereof are not repeated herein. The bit-line contact 313 may be formed in the dielectric layer 121 with a procedure similar to that illustrated in FIGS. 4 and 5, and descriptions thereof are not repeated herein. In a cross-sectional perspective, the bit-line contact 313 may be disposed on the channel layer 211. In a top-view perspective, the bit-line contact 313 may be topographically aligned with the storage node structure 510 or the channel layer 211.

With reference to FIGS. 37 and 38, a dielectric layer 129 may be formed on the dielectric layer 121 and cover the bit-line contact 313. In some embodiments, the dielectric layer 129 may be formed of, for example, silicon oxide, borophosphosilicate glass, undoped silicate glass, fluorinated silicate glass, low-k dielectric materials, the like, or a combination thereof. In some embodiments, the dielectric layer 129 may be formed by, for example, chemical vapor deposition, plasma-enhanced chemical vapor deposition, or other applicable deposition processes. It should be noted that the dielectric layer 129 is not shown in top-view diagrams for clarity.

With reference to FIGS. 37 and 38, the bit line 311 may be formed in the dielectric layer 129 and on the bit-line contact 313. In a top-view perspective, the plurality of bit lines 311 may be arranged along the Y direction. Each bit line 311 may extend along the direction X. In some embodiments, a plurality of bit-line trenches (not shown) may be formed in the dielectric layer 129. A conductive material (not shown) may be deposited to completely fill the bit-line trenches. A planarization process, such as chemical mechanical polishing, may be performed until the top surface of the dielectric layer 129 is exposed to remove excess material, provide a substantially flat surface for subsequent processing steps, and concurrently form the plurality of bit lines 311. In some embodiments, the conductive material may be, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

One aspect of the present disclosure provides a semiconductor device including a substrate; a channel layer positioned over the substrate, extending along a first direction perpendicular to a top surface of the substrate, and including an inverted trapezoid cross-sectional profile; and a word line including a word-line dielectric layer conformally and laterally surrounding the channel layer, and a word-line conductive layer laterally and partially surrounding the word-line dielectric layer, extending along a second direction parallel to the top surface of the substrate, and including an inverted trapezoid cross-sectional profile.

Another aspect of the present disclosure provides a semiconductor device including a substrate; a channel layer positioned over the substrate and extending along a first direction perpendicular to a top surface of the substrate, wherein a width of a top surface of the channel layer is greater than a width of a bottom surface of the channel layer; and a word line including a word-line dielectric layer conformally and laterally surrounding the channel layer, and a word-line conductive layer laterally and partially surrounding the word-line dielectric layer and extending along a second direction parallel to the top surface of the substrate, wherein a width of a top surface of the word-line conductive layer is greater than a width of a bottom surface of the word-line conductive layer.

Another aspect of the present disclosure provides a method for fabricating a semiconductor device including providing a substrate; forming a lower dielectric layer over the substrate; forming a middle dielectric layer on the lower dielectric layer; forming a word-line trench penetrating the middle dielectric layer, exposing the lower dielectric layer, and including an inverted trapezoid cross-sectional profile; forming a word-line conductive layer filling the word-line trench; forming an upper dielectric layer on the middle dielectric layer; forming a channel opening penetrating the upper dielectric layer, the word-line conductive layer, and the lower dielectric layer to expose the substrate; and conformally forming a word-line dielectric layer on a sidewall of the channel opening; and forming a channel layer filling the channel opening. The word-line conductive layer and the word-line dielectric layer together configure a word line.

Due to the design of the semiconductor device of the present disclosure, the process window for forming the channel layer 211 may be increased by employing the word-line conductive layer 411 and the channel layer 211 with the inverted trapezoid cross-sectional profile. As a result, the defect for fabricating the semiconductor device 1A may be decreased and the yield for fabricating the semiconductor device 1A may be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate;
a channel layer positioned over the substrate and extending along a first direction perpendicular to a top surface of the substrate, wherein a width of a top surface of the channel layer is greater than a width of a bottom surface of the channel layer; and
a word line comprising:
a word-line dielectric layer conformally and laterally surrounding the channel layer; and
a word-line conductive layer laterally and partially surrounding the word-line dielectric layer and extending along a second direction parallel to the top surface of the substrate, wherein a width of a top surface of the word-line conductive layer is greater than a width of a bottom surface of the word-line conductive layer;
wherein the word-line dielectric layer comprises a high-k dielectric material, silicon oxide, silicon nitride, silicon oxynitride, or a combination thereof.

2. The semiconductor device of claim 1, further comprising a bit line positioned under the channel layer and electrically coupled to the channel layer.

3. The semiconductor device of claim 2, further comprising a bit-line contact positioned between the channel layer and the bit-line contact.

4. The semiconductor device of claim 3, wherein the bit line is positioned in the substrate and extending along a third direction perpendicular to the second direction.

5. The semiconductor device of claim 3, wherein the bit line is positioned on the substrate and extending along a third direction perpendicular to the second direction.

6. The semiconductor device of claim 3, further comprising a storage node structure positioned on the channel layer and electrically connected to the channel layer.

7. The semiconductor device of claim 6, wherein the storage node structure comprises:
a first electrode layer positioned on the channel layer and electrically connected to the channel layer;
a second electrode layer positioned on the first electrode layer; and
a middle insulating layer positioned between the first electrode layer and the second electrode layer to electrically isolate the first electrode layer and the second electrode layer.

8. The semiconductor device of claim 1, further comprising a bit line positioned on the channel layer and electrically coupled to the channel layer.

9. The semiconductor device of claim 8, further comprising a bit-line contact positioned between the bit line and the channel layer.

10. The semiconductor device of claim 9, further comprising a storage node structure positioned under the channel layer and electrically connected to the channel layer.

11. The semiconductor device of claim 1, wherein the channel layer comprises doped polycrystalline silicon, doped polycrystalline germanium, or doped polycrystalline silicon germanium.

12. The semiconductor device of claim 1, wherein the word-line conductive layer comprises tungsten, cobalt, zirconium, tantalum, titanium, aluminum, ruthenium, copper, metal carbides, metal nitrides, transition metal aluminides, or a combination thereof.
